(19) United States
(12) Patent Application Publication
(10) Pub. No.: US 2013/0069680 A1
(43) Pub. Date: Mar. 21, 2013

(54) RISERS INCLUDING A PLURALITY OF HIGH ASPECT RATIO ELECTRICAL CONDUITS AND SYSTEMS AND METHODS OF MANUFACTURE AND USE THEROF

(71) Applicants: Koby L. Duckworth, Newberg, OR (US); Eric Hill, Portland, OR (US); Mike Jolley, Beaverton, OR (US); Kurt Schultz, Banks, OR (US); Jody Curtis, Portland, OR (US)

(72) Inventors: Koby L. Duckworth, Newberg, OR (US); Eric Hill, Portland, OR (US); Mike Jolley, Beaverton, OR (US); Kurt Schultz, Banks, OR (US); Jody Curtis, Portland, OR (US)

(73) Assignee: Cascade Microtech, Inc., Beaverton, OR (US)

(21) Appl. No.: 13/610,076

(22) Filed: Sep. 11, 2012

Related U.S. Application Data
(60) Provisional application No. 61/535,812, filed on Sep. 16, 2011.

(51) Int. Cl. G01R 1/073; H05K 3/10; H05K 1/11

(52) U.S. Cl. 324/754.03; 324/755.01; 174/261; 427/58

(57) ABSTRACT

Risers including a plurality of high aspect ratio electrical conduits, as well as systems and methods of manufacture and/or use of the risers and/or the high aspect ratio electrical conduits. The systems and methods may include incorporation of the plurality of high aspect ratio electrical conduits within a substantially planar body that may include and/or be formed from a solid dielectric material. The plurality of electrical conduits may be configured to conduct a plurality of electric currents between a first surface of the body and a second, substantially opposed, surface of the body. The surfaces may include a plurality of contact pads configured to provide a robust and/or corrosion-resistant surface and/or to improve electrical contact between the riser and another device. The risers also may include a layered structure, wherein the layers are sequentially formed to increase a thickness of the riser and/or the aspect ratio of the electrical conduits.

### RELATED APPLICATION

This application claims priority to United States Provisional Patent Application Ser. No. 61/535,812, which was filed on Sep. 16, 2011, and the complete disclosure of which is hereby incorporated by reference.

### FIELD OF THE DISCLOSURE

The present disclosure is directed generally to risers that include a plurality of high aspect ratio electric conduits that may transfer a plurality of electric currents between a first side of the riser and a second side of the riser, systems that include the risers, and methods of manufacturing and/or using the risers.

### BACKGROUND OF THE DISCLOSURE

The size of discrete circuit elements present on an electronic device, such as an integrated circuit device, continues to decrease. In addition, the number of bond and/or test pads that may be present on an individual die is increasing, leading to smaller and smaller pitches (i.e., distances) between adjacent pads, as well as smaller lengths, widths, and/or surface areas for individual pads. These changes represent significant challenges for manufacturing, testing, and/or packaging of the electronic devices due to the precise nature of the manufacturing steps that may be needed to physically define and/or spatially align the various layers present within the electronic devices, to contact the electronic devices with test probes during testing, and/or to assemble the electronic devices within a package.

In addition, the length of vertical interconnects, which are present within the electronic devices and/or within test structures and/or assembly structures that may be configured to electrically contact the electronic devices, continues to increase. Vertical interconnects also may be referred to herein as contacts, vias, and/or electrical conduits. This increase in vertical interconnect length, coupled with the decrease in pad pitch and a decrease in vertical interconnect cross-sectional area that may be needed to accommodate the decreased pitch, may produce a need for high aspect ratio (A/R) vertical interconnects, in which the length of the vertical interconnect is much greater than a characteristic cross-sectional dimension.

Current manufacturing technologies may provide for horizontal interconnects, such as horizontal metal lines that may be utilized in the backend architecture of electronic devices, that may include large aspect ratios. However, these horizontal metal wires are created using manufacturing processes that may provide for lithographically defining an entire length of the horizontal interconnect.

In contrast, current manufacturing technologies typically define vertical interconnects by lithographically defining their cross-sectional area and then using one or more etch process to define the length of the vertical interconnect (either by defining a void in a dielectric material into which the vertical interconnect may be deposited or by defining the vertical interconnect itself). The etch process may be followed by one or more deposition processes, which may deposit either a dielectric material around an already defined vertical interconnect or may deposit the vertical interconnect within the already defined void. While these manufacturing technologies may provide for the creation of vertical interconnects with relatively smaller aspect ratios, inherent limitations of both the etch and the deposition processes may preclude their use to produce high aspect ratio vertical interconnects.

High aspect ratio vertical interconnects may be utilized in a variety of processes and/or architectures. As an illustrative, non-exclusive example, a riser, or spacer, present within a probe head that may be utilized for testing of an electronic device may include a thickness and vertical interconnect pitch that falls in the high aspect ratio regime. As another illustrative, non-exclusive example, through silicon vias, which may be utilized to electrically connect an electronic device that is present on a first side of a substrate with a pad and/or an electronic device that is present on a second, substantially opposed, side of the substrate, may include and/or be high aspect ratio vertical interconnects. Thus, there exists a need for high aspect ratio vertical interconnects, as well as for systems and methods of manufacture and use thereof.

### SUMMARY OF THE DISCLOSURE

Risers including a plurality of high aspect ratio electrical conduits, as well as systems and methods of manufacture and/or use of the risers and/or the high aspect ratio electrical conduits. The systems and methods may include incorporation of the plurality of high aspect ratio electrical conduits within a substantially planar body that may include and/or be formed from a solid dielectric material. The plurality of electrical conduits may be configured to conduct a plurality of electric currents between a first surface of the body and a second, substantially opposed, surface of the body. The surfaces may include a plurality of contact pads that are configured to provide a robust and/or corrosion-resistant surface and/or to improve electrical contact between the riser and another device. The risers also may include a layered structure, in which the layers are formed sequentially to increase a thickness of the riser and/or the aspect ratio of the electrical conduits.

In some embodiments, the plurality of electrical conduits may be formed prior to the body. In some embodiments, the plurality of electrical conduits may be formed and/or placed within a plurality of voids formed within the body. In some embodiments, the plurality of electrical conduits may be formed in the body. In some embodiments, the plurality of electrical conduits includes a plurality of metallic bump pads that are stacked on top of one another to form a stack of metallic bump pads. In some embodiments, the plurality of electrical conduits includes a plurality of metallic wires. In some embodiments, the plurality of electrical conduits includes a plurality of deposited electrical conduits. In some embodiments, the plurality of electrical conduits includes a conductivity-enhancing material that is incorporated into the dielectric material.

### BRIEF DESCRIPTION OF THE DRAWINGS

FIG. 1 is a schematic representation of illustrative, non-exclusive examples of a test system that includes a probe head assembly that may include a device under test riser according to the present disclosure.

FIG. 2 is a schematic representation of an illustrative, non-exclusive example of a portion of a probe head assembly that includes a device under test riser according to the present disclosure.

FIG. 3 is a schematic representation of illustrative, non-exclusive examples of a device under test riser according to the present disclosure that may be operatively attached to a substrate.

FIG. 4 is a schematic representation of illustrative, non-exclusive examples of a device under test riser according to the present disclosure that may be formed on a substrate.

FIG. 5 is a flowchart depicting methods of forming a device under test riser according to the present disclosure.

FIG. 6 is another flowchart depicting methods of forming a device under test riser according to the present disclosure.

FIG. 7 is another flowchart depicting methods of forming a device under test riser according to the present disclosure.

FIG. 8 is a flowchart depicting illustrative, non-exclusive examples of methods of forming and/or using device under test risers according to the present disclosure.

FIGS. 9-13 are schematic representations of process flows that may be utilized to create a device under test riser according to the present disclosure that includes a plurality of metallic bump pads.

FIGS. 14-16 are schematic representations of process flows that may be utilized to produce a contact pad on device under test risers according to the present disclosure.

FIGS. 17-18 are schematic representations of illustrative, non-exclusive examples of device under test risers that include one or more passive electronic components according to the present disclosure.

FIGS. 19-22 are schematic representations of illustrative, non-exclusive examples of process flows that may be utilized to create a device under test riser according to the present disclosure that includes a plurality of metallic wires.

FIGS. 23-24 are schematic representations of illustrative, non-exclusive examples of device under test risers according to the present disclosure that include a plurality of ferromagnetic wires.

FIGS. 25-29 are schematic representations of illustrative, non-exclusive examples of process flows that may be utilized to create a device under test riser according to the present disclosure.

FIGS. 30-31 are schematic representations of illustrative, non-exclusive examples of process flows that may be utilized to create a device under test riser according to the present disclosure.

FIG. 32 is a schematic representation of an illustrative, non-exclusive example of a device under test riser according to the present disclosure assembled on a substrate.

FIGS. 33-34 are schematic representations of illustrative, non-exclusive examples of process flows that may be utilized to assemble a device under test riser according to the present disclosure on a substrate.

FIGS. 35-36 are schematic representations of illustrative, non-exclusive examples of process flows that may be utilized to assemble a device under test riser according to the present disclosure on a substrate.

FIG. 37 is a schematic representation of an illustrative, non-exclusive example of a portion of a probe head that includes a plurality of device under test risers according to the present disclosure.

FIGS. 38-44 are schematic representations of process flows that may be utilized to create a device under test riser according to the present disclosure that includes a plurality of composite pillars.

### DETAILED DESCRIPTION AND BEST MODE OF THE DISCLOSURE

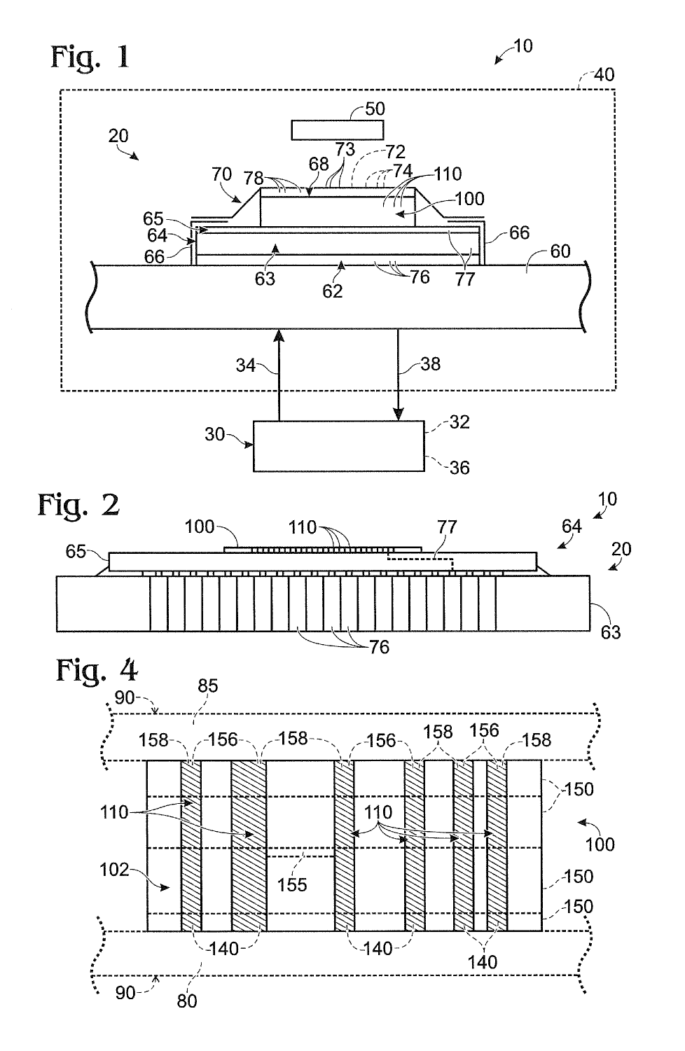

FIG. 1 is a schematic, partially exploded, representation of illustrative, non-exclusive examples of a test system 10 that may include a probe head assembly 20 that may include a device under test (DUT) riser 100 according to the present disclosure. In FIG. 1, test system 10 may include a control system 30 that is in electrical communication with probe head assembly 20. Control system 30 may be configured to provide a test signal 34 to probe head assembly 20, which may be in electrical communication with a device under test (DUT) 50 and which may provide a corresponding test signal to DUT 50. Similarly, DUT 50 may generate a resultant signal from the test signal that is supplied thereto, and probe head assembly 20 may provide a corresponding resultant signal 38 to control system 30. At least a portion of test system 10, such as probe head assembly 20 and/or DUT 50, may be contained within an enclosure 40.

Control system 30 may include any suitable structure that is configured to provide test signal 34 to the probe head assembly, receive resultant signal 38 from the probe head assembly, and/or control the operation of test system 10, including controlling the operation of other components thereof. As an illustrative, non-exclusive example, control system 30 may include a signal generator 32 that is configured to generate the test signal and/or a signal analyzer 36 that is configured to receive and/or analyze the resultant signal.

In general, control system 30 may be configured to control the operation of test system 10, and test system 10, probe head assembly 20, and/or DUT riser 100 may be utilized to test the functionality and/or performance of DUT 50. As discussed in more detail herein, this may include electrically and/or optically testing DUT 50. Illustrative, non-exclusive examples of DUTs 50 according to the present disclosure include any suitable semiconductor device, electronic device, microprocessor, integrated circuit, memory device, and/or controller.

Probe head assembly 20 may include and/or be in electrical and/or mechanical communication with a plurality of components. In the illustrative, non-exclusive example of FIG. 1, the probe head assembly may be mounted on a load board 60 and may include a wide pitch interposer 62, a space transformer assembly 64 (which may include and/or be in electrical and/or physical contact with DUT riser 100), a probe head frame 66, a narrow and/or a fine pitch interposer 68, and/or device under test contacting assembly 70.

Load board 60 may include any suitable structure that is configured to function as a mounting and/or bearing surface for at least a portion of the components of the probe head assembly. Wide pitch interposer 62 may include a substantially planar structure that includes a plurality of wide pitch interposer electrical conduits 76 that may be configured to transfer a plurality of electric currents between a first and a second surface thereof without substantially changing a spatial relationship among the plurality of electric conduits. A pitch, or spacing, among the plurality of wide pitch interposer electrical conduits that are contained within the wide pitch interposer may be on the order of 0.8 millimeters (mm), while a length of the wide pitch interposer electrical conduits may be less than 5 mm, less than 4 mm, less than 3 mm, less than 2 mm, or less than 1 mm.

Space transformer assembly 64 may include a wide pitch riser 63 and a space transformer 65, and space transformer assembly 64 includes a plurality of space transformer electrical conduits 77 that are in electrical communication with the plurality of wide pitch interposer electrical conduits 76 and also with a plurality of narrow pitch interposer electrical conduits 78 of narrow pitch interposer 68. Thus, space transformer assembly 64 may be configured to decrease, route, change, adjust, and/or transform a spacing of the plurality of space transformer electrical conduits from the relatively wide spacing of wide pitch interposer 62 to a narrower spacing that may be associated with the electrical conduits of narrow pitch interposer 68.

As discussed in more detail herein, DUT riser 100 may be in electrical and/or physical communication with both space transformer assembly 64 and narrow pitch interposer 68, and DUT riser 100 may include a plurality of DUT riser electrical conduits 110, which additionally or alternatively may be referred to herein as riser electrical conduits 110, high aspect ratio electrical conduits 110, and/or electrical conduits 110. DUT riser electrical conduits 110 may be configured to transfer the plurality of electrical currents between the space transformer assembly and the narrow pitch interposer. A pitch, or spacing, and an arrangement of the plurality of DUT riser electrical conduits 110 may be similar to, matched to, and/or complementary to a pitch, or spacing, and an arrangement of the plurality of narrow pitch interposer electrical conduits 78. However, a thickness of DUT riser 100 may be significantly greater than a thickness of narrow pitch interposer 68, and a length of the plurality of DUT riser electrical conduits 110 also may be significantly greater than a length of the plurality of narrow pitch interposer electrical conduits 78. Thus, and as discussed in more detail herein, an aspect ratio (A/R) of the plurality of DUT riser electrical conduits may preclude the use of standard manufacturing technologies for their formation. Additionally or alternatively, it is within the scope of the present disclosure that the thickness of DUT riser 100 may be at least substantially the same as and/or less than the thickness of narrow pitch interposer 68 and/or that probe head assembly 20 may not include DUT riser 100.

Device under test contacting assembly 70 may include any suitable structure that is configured to form a plurality of electrical connections with DUT 50 and/or to provide test signals 34 to and/or receive resultant signals 38 from the DUT. As an illustrative, non-exclusive example, the DUT contacting assembly may include a plurality of probe tips 73 that are configured to provide the plurality of electrical connections. As another illustrative, non-exclusive example, DUT contacting assembly 70 may include a membrane contacting layer 72 and/or a plurality of rocking beam interposers 74. Membrane contacting layer 72 may, additionally or alternatively, be referred to herein as a membrane contacting assembly 72. Illustrative, non-exclusive examples of test systems 10, membrane contacting layers 72, and/or rocking beam interposers 74 are disclosed in U.S. Provisional Patent Application Nos. 61/410,242, 61/446,379, and 61/484,116 and in U.S. Pat. Nos. 5,914,613, 6,256,882, and 7,862,391, the complete disclosures of which are hereby incorporated by reference.

DUT riser 100 may be configured to change, or adjust, a distance between space transformer assembly 64 and/or space transformer 65 and DUT contacting assembly 70. Additionally or alternatively, when the DUT contacting assembly includes membrane contacting assembly 72, DUT riser 100 may be configured to adjust a force that is applied to membrane contacting assembly 72 by space transformer assembly 64, to adjust a deflection, or tension, of the membrane contacting assembly when mounted within probe head assembly 20, and/or to provide clearance between membrane contacting assembly 72 and an upper surface of space transformer 65 and/or one or more components that may be present thereon. As an illustrative, non-exclusive example, a thickness of space transformer assembly 64 and/or space transformer 65 may vary depending upon the particular DUT that is to be tested, or probed, by test system 10. Under these conditions, DUT riser 100 may be configured to account for this variation in the thickness of space transformer assembly 64 and/or space transformer 65. As an illustrative, non-exclusive example, a space transformer assembly and/or space transformer with a decreased thickness may be utilized with a DUT riser with an increased thickness. Conversely, a space transformer assembly and/or space transformer with an increased thickness may be utilized with a DUT riser with a decreased thickness.

FIG. 1 is an illustrative, non-exclusive example of test system 10 including probe head assembly 20 that may be utilized with the systems and methods according to the present disclosure. As such, additional components may be present within test system 10 and/or probe head assembly 20, one or more components illustrated in FIG. 1 may not be present in test system 10 and/or probe head assembly 20, and/or one or more components illustrated in FIG. 1 may be combined and/or formed simultaneously with one or more other components illustrated in FIG. 1, without departing from the scope of the present disclosure. In addition, FIG. 1 schematically illustrates DUT 50 as being vertically above probe head assembly 20 that includes DUT riser 100. However, this illustrative, non-exclusive example is so illustrated simply for clarity and consistency with the subsequent Figures that further illustrate DUT riser 100. Thus, test system configurations in which DUT 50 is vertically below probe head assembly 20, as well as any other suitable DUT to probe head configuration, are also within the scope of the present disclosure.

Furthermore, while the systems and methods disclosed herein are specifically applicable to DUT riser 100 and are so discussed herein, there are a number of other applications in which a high aspect ratio, narrow pitch device may be utilized. Thus, while the proceeding and subsequent discussion will, for convenience, refer to DUT riser 100, it is within the scope of the present disclosure that DUT riser 100 also may be referred to herein as including and/or forming a portion of a spacer 100, an interposer 100, and/or an electronic device 100. Additionally or alternatively, DUT riser electrical conduits 110 also may be referred to herein as high aspect ratio vertical interconnects 110, through silicon vias (TSVs) 110, vias 110, high aspect ratio vias 110, contacts 110, electrical pillars 110, and/or high aspect ratio contacts 110.

FIG. 2 is a schematic representation of an illustrative, non-exclusive example of a portion of probe head assembly 20 and/or space transformer assembly 64 that includes DUT riser 100 according to the present disclosure. In FIG. 2, wide pitch riser 63 includes wide pitch interposer electrical conduits 76 and is in electrical communication with and operatively attached to space transformer 65, which includes space transformer electrical conduits 77 (one of which is schematically illustrated in FIG. 2). In addition, space transformer 65 is in electrical communication with DUT riser 100, which includes DUT riser electrical conduits 110. It is within the scope of the present disclosure that wide pitch riser 63 and space transformer 65 may be operatively attached to one another and in electrical communication with each other using any suitable structure.

Similarly, and as discussed in more detail herein, DUT riser 100 may be in physical and/or electrical communication with space transformer 65 using any suitable structure. As an illustrative, non-exclusive example, DUT riser 100 may be formed separately from and operatively attached to space transformer 65. As another illustrative, non-exclusive example, DUT riser 100 may be formed on, formed with, and/or form a portion of space transformer 65.

FIG. 3 provides an illustrative, non-exclusive example of a DUT riser 100 that may be formed separately from and operatively attached to a substrate 90, such as space transformer assembly 64. DUT riser 100 includes a substantially planar body 102 that includes a first surface 104, or side 104, and a second, substantially opposed, surface 106, or side 106. DUT riser 100 also includes a plurality of DUT riser electrical conduits 110, which also may be referred to herein as a plurality of electrical conduits 110 and/or as electrical conduits 110.

DUT riser electrical conduits 110 may be configured to conduct a plurality of electric currents between first surface 104 and second surface 106. Electrical conduits 110 may refer to a specific group of electrical conduits that are present within DUT riser 100. Thus, it is within the scope of the present disclosure that the DUT riser also may include other electrical conduits in addition to the plurality of electrical conduits 110 or that the plurality of electrical conduits 110 may include each electrical conduit that is present within DUT riser 100.

Body 102 may include any suitable structure that is configured to define first surface 104 and second surface 106, to provide mechanical support to electrical conduits 110, to electrically insulate electrical conduits 110 from one another, and/or to provide mechanical support for one or more electronic devices and/or structures that may be mounted on and/or coupled to first surface 104 and/or second surface 106 and/or that may be located within body 102. Illustrative, non-exclusive examples of suitable materials for a body 102 include a solid dielectric material 108 including polymers, semiconductors, epoxies, silicon oxide, polyimides, photopolymers, spin-on-glass, rigid dielectric materials, non-resilient dielectric materials, and/or non-elastomeric dielectric materials.

As discussed in more detail herein, body 102 may be formed around and/or formed after electrical conduits 110. However, electrical conduits 110 also may be formed after and/or placed within body 102. Illustrative, non-exclusive examples of electrical conduits 110 include any suitable conductive material, metal, copper, copper alloy, gold, gold alloy, nickel, nickel alloy, aluminum, carbon nanotubes, graphene, doped semiconductor material, rigid conductive material, at least substantially rigid conductive material, and/or combinations thereof.

Substrate 90 may include any suitable structure that is configured to be operatively attached to and/or in electrical communication with DUT riser 100. Illustrative, non-exclusive examples of substrates 90 include any suitable semiconductor package (including a package that might be utilized during packaging and assembly of the DUT), wide pitch interposer, and/or narrow pitch interposer. It is within the scope of the present disclosure that the materials of construction of DUT riser 100 and/or substrate 90 may be selected such that a coefficient of thermal expansion of the substrate may be at least substantially similar to, if not the same as, a coefficient of thermal expansion of the DUT riser. This may include coefficients of thermal expansion that differ by less than 20%, less than 15%, less than 10%, less than 7.5%, less than 5%, less than 2.5%, less than 1%, or less than 0.5%.

Electrical conduits 110 may include any suitable structure that is configured to conduct the plurality of electric currents between first surface 104 and second surface 106. As an illustrative, non-exclusive example, and as discussed in more detail herein, electrical conduits 110 may include a plurality of metallic bump pads 112, which also may be referred to as a plurality of stud bumps 112 and/or a plurality of bump pads 112 that are in electrical communication with one another and that may, additionally or alternatively, also be referred to herein as a pillar of metallic bump pads 112.

Illustrative, non-exclusive examples of suitable bump pads 112 include bump pads that may be the same as, or at least substantially similar to, metallic bumps that are utilized in a standard stud bump process. When electrical conduits 110 include metallic bump pads 112, the metallic bump pads may be added to the plurality of electrical conduits in a sequential fashion, with the number of metallic bump pads present in an individual electrical conduit being increased until a desired length of the electrical conduit is reached. Each of the plurality of metallic bump pads may include a substantially circular, or spheroidal, shape and may be stacked, one on top of the other, to produce the electrical conduits. Thus, each of the electrical conduits may include a continuous, nonlinear, and/or substantially periodic longitudinal cross-sectional shape and/or profile.

As another illustrative, non-exclusive example, and as discussed in more detail herein, electrical conduits 110 may include a plurality of metallic wires 114, which also may be referred to herein as a plurality of wire pillars 114. The metallic wires may be formed separately from and placed within the DUT riser and may be randomly, regularly, and/or systematically located within body 102 using any suitable system and/or method, an illustrative, non-exclusive example of which includes a pick-and-place process that may place the metallic wires into body 102 singularly or in groups. Additional illustrative, non-exclusive examples of methods of locating metallic wires 114 within body 102 are discussed in more detail herein.

It is within the scope of the present disclosure that metallic wires 114 may be formed in any suitable manner and/or include any suitable material and/or materials of construction. As an illustrative, non-exclusive example, metallic wires 114 may include and/or be any suitable electrically conductive material, illustrative, non-exclusive examples of which include metals, copper, aluminum, gold, silver, graphite, carbon nanotubes, conductive polymers, and/or conductive and/or doped semiconductor materials. The metallic wires also may be referred to herein as conductive wires 114 and/or conductive pillars 114. Illustrative, non-exclusive examples, of methods of forming metallic wires 114 may include extruding, drawing, rolling, deposition, lithography, and/or etching.

As yet another illustrative, non-exclusive example, and as also discussed in more detail herein, electrical conduits 110 also may include a plurality of deposited electrical conduits 116. Deposited electrical conduits 116 may be formed using any suitable process, illustrative, non-exclusive examples of which include physical vapor deposition, chemical vapor deposition, evaporation, sputtering, epitaxial growth, and/or plating. When electrical conduits 110 include deposited electrical conduits 116, a cross-sectional shape of the deposited electrical conduits and/or a location of the deposited electrical conduits may be defined by a lithographic process and/or by an etching process.

It is within the scope of the present disclosure that deposited electrical conduits 116 may be deposited in a single process step, or layer. However, it is also within the scope of the present disclosure that deposited electrical conduits 116 may be deposited in a series, or plurality, of process steps that are performed to produce the composite electrical conduits in a plurality of layers, with each layer of the plurality of layers increasing a total length of the deposited electrical conduits. When the deposited electrical conduits are deposited in a plurality of layers, the deposited electrical conduits also may be referred to herein as composite pillars 117, layered pillars 117, and/or stacked pillars 117.

As yet another illustrative, non-exclusive example, and as also discussed in more detail herein, electrical conduits 110 also may include a plurality of metallic conduits 118 that are formed within a void 120 present within body 102. Metallic conduits 118 may be formed in any suitable manner, including those discussed in more detail herein with reference to deposited conduits 116. Similarly, voids 120 may be formed in any suitable manner, illustrative, non-exclusive examples of which include etching, mechanical drilling, laser drilling, and/or lithography.

As yet another illustrative, non-exclusive example, and as also discussed in more detail herein, electrical conduits 110 may include a conductive region 122 that is incorporated into, or formed in, body 102. As illustrative, non-exclusive examples, conductive region 122 may include a dopant that may be implanted into dielectric material 108 and/or a conductive phase region within body 102 that may be formed from a material with a conductivity that varies with phase, an illustrative, non-exclusive example of which includes a chalcogenide glass.

DUT riser 100 also may include one or more contact pads 130 that are configured to provide an increased surface area and/or increased durability region for contact between electrical conduits 110 and a device that may be in electrical communication with DUT riser 100, such as substrate 90, space transformer assembly 64, fine pitch interposer 68, device under test contacting assembly 70, membrane contacting layer 72, and/or rocking beam interposer 74 (as illustrated in FIG. 1). Contact pads 130 may include any suitable size, location, and/or orientation and may be in electrical communication with one or more electrical conduits 110.

As an illustrative, non-exclusive example, and as shown at 132 in FIG. 3, the contact pads may be in electrical communication with a plurality of electrical conduits 110, including two, three, four, five, six, eight, ten, or more than ten electrical conduits 110. As another illustrative, non-exclusive example, and as shown at 134 in FIG. 3, a central axis of the contact pads may be aligned with a central axis of the electrical conduits with which the contact pads are in electrical communication.

As yet another illustrative, non-exclusive example, and as shown at 136 in FIG. 3, the central axis of the contact pads may not be aligned with the central axis of the electrical conduits with which the contact pads are in electrical communication and/or the contact pads may be aligned with an electrical pad 92, or another complementary structure, that is present on substrate 90. This may provide for registration, or alignment, of contact pads 130 with electrical pads 92 even if electrical conduit 110 is not aligned, or not perfectly aligned, with electrical pad 92.

As yet another illustrative, non-exclusive example, contact pads 130 may include planar contact pads that include a circular, square, and/or rectangular shape. A minimum length, or dimension, of the contact pads may be less than 150 micrometers (um), including less than 140 um, less than 130 um, less than 120 um, less than 110 um, less than 100 um, less than 90 um, less than 80 um, less than 70 um, less than 60 um, less than 50 um, less than 40 um, less than 30 um, less than 20 um, less than 15 um, or less than 10 um. The minimum length, or dimension, of the contact pads also may be greater than 1 um, greater than 2.5 um, greater than 5 um, greater than 10 um, greater than 15 um, or greater than 20 um.

Additionally or alternatively, a root mean square surface roughness of the contact pads may be less than a threshold surface roughness. Illustrative, non-exclusive examples of threshold surface roughnesses according to the present disclosure include threshold surface roughnesses of less than 10 um, less than 9 um, less than 8 um, less than 7 um, less than 6 um, less than 5 um, less than 4 um, less than 3 um, less than 2 um, less than 1 um, less than 0.5 um, or less than 0.25 um.

Contact pads 130 also may include an abrasion-resistant surface 138 and/or a corrosion-resistant surface 142 that is/are configured to increase a durability of the contact pads. As an illustrative, non-exclusive example, abrasion-resistant surface 138 and/or corrosion-resistant surface 142 may include one or more surface layers and/or films, illustrative, non-exclusive examples of which include hard gold alloys, ruthenium, osmium, iridium, diamond-like carbon, and/or rhodium. In addition, first surface 104 and/or second surface 106 of DUT riser 100 may include and/or be covered by an abrasion-resistant coating 176.

DUT riser 100 may be formed in any suitable manner and/or with any suitable process. As an illustrative, non-exclusive example, and as discussed in more detail herein, the DUT riser may be formed on an intermediate substrate and subsequently placed into electrical communication with substrate 90. When the DUT riser is formed on an intermediate substrate, it may be operatively attached to and/or placed into electrical communication with substrate 90 in any suitable manner and/or with any suitable process. As an illustrative, non-exclusive example, one or more attachment structures 140 may be configured to attach DUT riser 100 to substrate 90 and/or to provide electrical communication therebetween. Illustrative, non-exclusive examples of suitable attachment structures 140 according to the present disclosure include solder, adhesive, patterned conductive adhesive, anisotropically conductive adhesive, and/or rocking beam interposers, as discussed in more detail herein. Additionally or alternatively, DUT riser 100 may be in electrical communication with substrate 90 but not be operatively attached thereto. As an illustrative, non-exclusive example, the DUT riser may be mechanically pressed into electrical contact with substrate 90.

As discussed in more detail herein, the pitch, or spacing, of electrical conduits 110 associated with DUT riser 100 may be significantly less than the pitch, or spacing, of the electrical conduits associated with wide pitch interposer 62 (which is illustrated in FIG. 1). Illustrative, non-exclusive examples of pitches of DUT riser electrical conduits 110 according to the present disclosure include pitches of less than 150 um, less than 140 um, less than 130 um, less than 120 um, less than 110 um, less than 100 um, less than 90 um, less than 80 um, less than 70 um, less than 60 um, less than 50 um, less than 40 um, less than 30 um, less than 20 um, less than 15 um, or less than 10 um. Additionally or alternatively, DUT riser electrical conduits 110 according to the present disclosure may include pitches of greater than 0.5 um, greater than 1 um, greater than 2.5 um, greater than 5 um, greater than 10 um, greater than 15 um, or greater than 20 um.

In addition, the DUT riser may include any suitable number of electrical conduits 110. Illustrative, non-exclusive examples of the number of electrical conduits present within DUT riser 100 include at least 1,000 electrical conduits, at least 2,000, at least 2,500, at least 5,000, at least 10,000, at least 15,000, at least 20,000, at least 25,000, at least 50,000, at least 75,000, at least 100,000, at least 250,000, at least 500,000, at least 750,000, or at least 1,000,000 electrical conduits.

DUT risers 100 also may include any suitable thickness 144. Additionally or alternatively, electrical conduits 110 associated with the DUT riser also may include any suitable length. Illustrative, non-exclusive examples of DUT riser thicknesses according to the present disclosure include thicknesses of at least 25 um, at least 50 um, at least 5 um, at least 100 um, at least 150 um, at least 200 um, at least 250 um, at least 300 um, at least 400 um, at least 500 um, at least 750 um, at least 1000 um, 50-500 um, 100-400 um, 200-350 um, or 150-300 um.

As discussed in more detail herein, electrical conduits 110 associated with DUT riser 100 may include high aspect ratio electrical conduits. As used herein, the term “aspect ratio” may refer to a ratio of a length of a feature to a characteristic cross-sectional dimension of the feature. Illustrative, non-exclusive examples of characteristic cross-sectional dimensions according to the present disclosure include any suitable diameter, effective diameter, and/or minimum cross-sectional dimension. Illustrative, non-exclusive examples of aspect ratios for DUT riser electrical conduits according to the present disclosure include aspect ratios of at least 4:1, at least 5:1, at least 6:1, at least 7:1, at least 8:1, at least 9:1, at least 10:1, at least 12:1, at least 14:1, at least 16:1, at least 18:1, at least 20:1, at least 22:1, at least 24:1, at least 26:1, at least 28:1, or at least 30:1.

Electrical conduits 110 associated with DUT riser 100 may be perpendicular to, or at least substantially perpendicular to, a plane defined by first surface 104 and/or second surface 106. As an illustrative, non-exclusive example, electrical conduits 110 may be within a threshold angle of being perpendicular to the first surface and/or the second surface. Illustrative, non-exclusive examples of threshold angles according to the present disclosure include threshold angles of less than 10 degrees, less than 8 degrees, less than 6 degrees, less than 4 degrees, or less than 2 degrees.

Each of the plurality of electric currents that are transferred between first surface 104 and second surface 106 of DUT riser 100 may include an amplitude of at least 0.5 amps, at least 0.75 amps, at least 1 amp, at least 1.25 amps, at least 1.5 amps, at least 1.75 amps, at least 2 amps, at least 2.25 amps, at least 2.5 amps, at least 3 amps, at least 3.5 amps, at least 4 amps, or at least 5 amps. Additionally or alternatively, each of the plurality of electric currents may be transferred through DUT riser 100 with a duty cycle of at least 10%, at least 15%, at least 20%, at least 25%, at least 30%, at least 35%, or at least 40%.

A plane defined by first surface 104 may be parallel to a plane defined by second surface 106 and/or may be within a threshold amount of being parallel to the plane defined by second surface 106, wherein the threshold amount may be defined as a difference between a maximum distance between first surface 104 and second surface 106 (or a maximum thickness of DUT riser 100) and a minimum distance between first surface 104 and second surface 106 (or a minimum thickness of DUT riser 100). Illustrative, non-exclusive examples of threshold amounts according to the present disclosure include threshold amounts of less than 15 um, less than 14 um, less than 12 um, less than 10 um, less than 8 um, less than 6 um, or less than 5 um.

Additionally and/or alternatively, the plane defined by first surface 104 and/or the plane defined by second surface 106 may be flat, at least substantially flat, and/or within a flatness threshold of being flat. Illustrative, non-exclusive examples of flatness thresholds according to the present disclosure include flatness thresholds of less than 20 um, less than 15 um, less than 10 um, less than 8 um, less than 6 um, or less than 5 um.

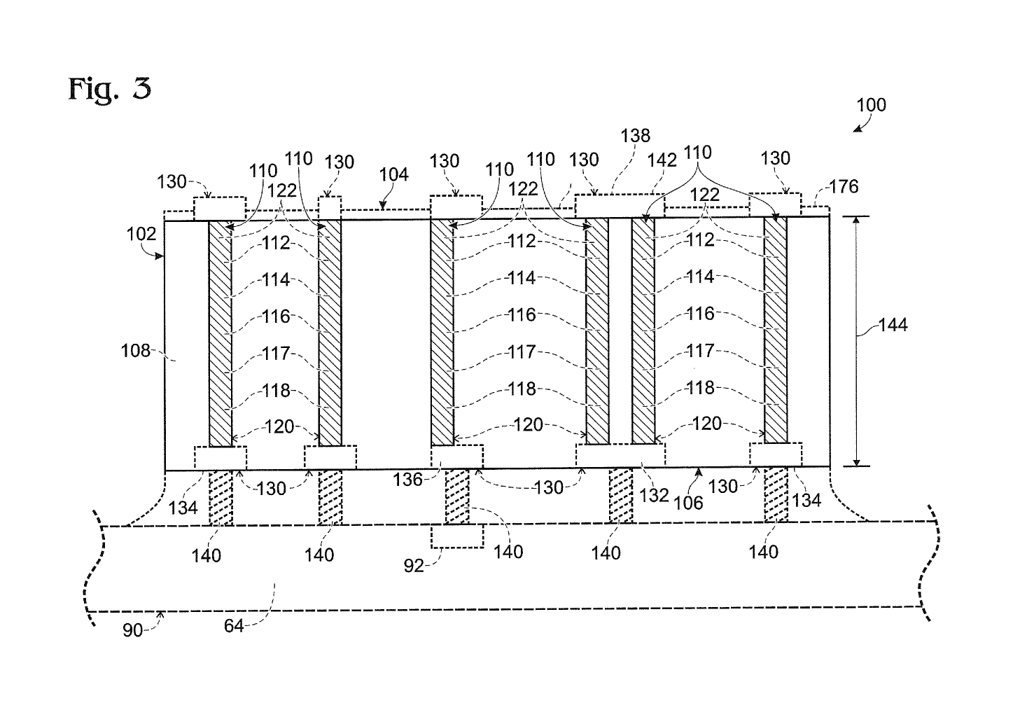

FIG. 4 provides an illustrative, non-exclusive example of a DUT riser 100 that may be formed on and/or from substrate 90. The DUT riser of FIG. 4 may include some or all of the illustrative, non-exclusive examples of structures, features, and/or dimensions that are discussed in more detail herein with reference to FIG. 3. In addition, the DUT riser of FIG. 3 may include some or all of the illustrative, non-exclusive examples of structures, features, and/or dimensions that are discussed herein with reference to FIG. 4.

As schematically illustrated in FIG. 4, DUT risers 100 according to the present disclosure optionally may include more than one layer 150, and in such an embodiment may be described as including a plurality of layers 150. In FIG. 4, four layers 150 are indicated, but it is within the scope of the present disclosure that a DUT riser 100 may include fewer or more layers 150, such as a single layer 150, two layers 150, three layers 150, or more than four layers 150. In addition, DUT riser 100 optionally may be located between and/or configured to provide a plurality of electrical connections between and/or conduct the plurality of electric currents between two substrates 90, such as, first device 80 and second device 85.

As schematically depicted in FIG. 4, DUT riser 100 may be formed on first device 80. It is within the scope of the present disclosure that DUT riser 100 may not be configured to be removed from the first device and/or may not be configured to be removed from the first device without damage to and/or destruction of the DUT riser, the first device, and/or attachment structure 140. When DUT riser 100 is formed on first device 80, it is within the scope of the present disclosure that the plurality of electrical conduits may be formed on the first device prior to application of body 102 to the first device. In contrast, body 102 may be applied to first device 80, with the plurality of electrical conduits being subsequently formed or otherwise inserted, created, and/or positioned within body 102. Additionally or alternatively, it is also within the scope of the present disclosure that DUT riser 100 and/or electrical conduits 110 thereof may be formed in and/or form a portion of first device 80.

Layers 150 may include any of the illustrative, non-exclusive examples of structures, features, and/or dimensions that are discussed in more detail herein with reference to DUT riser 100. Each of the plurality of DUT riser layers 150, when present, may be in electrical and physical contact with at least one other of the plurality of layers, and the electrical conduits associated with the layers may be configured and/or aligned to provide the plurality of electrical connections between first device 80 and second device 85. When the DUT riser includes a plurality of layers 150, electrical conduits 110 associated therewith may include composite, or layered, electrical conduits that are formed by the plurality of layers, as shown in FIG. 4.

DUT risers 100 that include layers 150 also may include one or more passive electronic components 155 that may be present between two or more layers of the DUT riser. Illustrative, non-exclusive examples of passive electronic components 155 according to the present disclosure include any suitable resistor, capacitor, inductor, transformer, and/or electrical conduit.

Passive electronic components 155, when present, may be configured to conduct an electric current between two or more of the electric conduits that are present within the DUT riser. As an illustrative, non-exclusive example, electrical conduits 110 may include a plurality of ground conduits 156, and passive electronic component 155 may be configured to electrically connect at least a portion, a substantial portion, a majority, or all of the plurality of ground conduits. As another illustrative, non-exclusive example, electrical conduits 110 may include a plurality of power supply conduits 158, and passive electronic components 155 may be configured to electrically connect at least a portion, a substantial portion, a majority, or all of the plurality of power supply conduits.

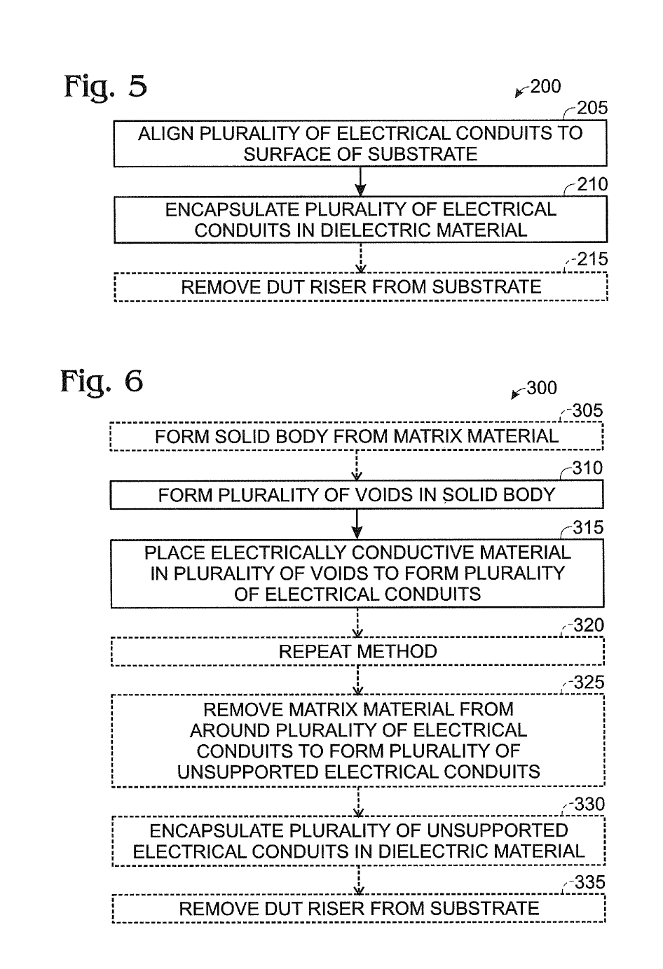

FIGS. 5-8 provide illustrative, non-exclusive examples of methods according to the present disclosure. These include methods of forming a DUT riser in FIGS. 5-7, as well as methods of finishing, assembling, and/or utilizing the DUT riser in FIG. 8. Although not required, the methods of FIGS. 5-8 may be used to form, finish, assemble, and/or utilize DUT risers 100 according to the present disclosure.

FIG. 5 is a flowchart depicting illustrative, non-exclusive examples of methods 200 according to the present disclosure of forming a DUT riser. Methods 200 may be broadly categorized as methods of forming a DUT riser, such as DUT riser 100, with such methods including the formation of the electrical conduits prior to the formation of a body and/or dielectric material that may surround, encapsulate, and/or insulate the electrical conduits from one another and/or define an external shape of the DUT riser.

Methods 200 include aligning a plurality of electrical conduits to a surface of a substrate at 205, and encapsulating the plurality of electrical conduits in a dielectric material at 210. The methods optionally also may include removing the DUT riser that may be formed by the method from the substrate, as indicated at 215.

Aligning the plurality of electrical conduits to the surface of the substrate at 205 may include the use of any suitable method and/or apparatus to accomplish the alignment. As an illustrative, non-exclusive example, the aligning may include attaching the plurality of electrical conduits directly to the surface of the substrate and/or attaching the plurality of electrical conduits to an intermediate layer that is formed on the surface of the substrate. As another illustrative, non-exclusive example, the aligning may include adhering the plurality of electrical conduits to the surface of the substrate.

As yet another illustrative, non-exclusive example, the aligning may include soldering, welding, brazing, and/or spot welding the plurality of electrical conduits to the substrate and/or alloying at least a portion of each of the plurality of electrical conduits with at least a portion of the surface of the substrate. It is within the scope of the present disclosure that the aligning may occur sequentially, with one, or several, of the plurality of electrical conduits being aligned on and/or affixed to the substrate prior to another one, or several, of the plurality of electrical conduits being aligned on and/or affixed to the substrate. However, it is also within the scope of the present disclosure that the aligning may occur simultaneously, such as when all, or at least substantially all, of the plurality of electrical conduits are aligned on and/or affixed to the substrate at the same, or at least substantially the same, time. As an illustrative, non-exclusive example, and as discussed in more detail herein, the plurality of electrical conduits may be fabricated separately from the substrate and/or may be fabricated on an intermediate substrate and then placed on the surface of the substrate using any suitable system and/or method, an illustrative, non-exclusive example of which includes a pick-and-place system and/or method. As yet another illustrative, non-exclusive example, the aligning may include establishing electrical communication between the plurality of electrical conduits and the surface of the substrate.

It is within the scope of the present disclosure that the aligning may include systematically aligning, randomly aligning, and/or regularly aligning When the aligning includes systematically aligning the plurality of electrical conduits, this may include selectively locating each of the plurality of electrical conduits such that a location of each of the plurality of electrical conduits, as well as a relative location of each of the plurality of electrical conduits with respect to the other of the plurality of electrical conduits, may correspond to a predetermined, fixed, and/or desired location and/or relative location. As an illustrative, non-exclusive example, this may include selectively locating each of the plurality of electrical conduits such that a location of each of the plurality of electrical conduits corresponds to a location of an electrical pad or other electrical contacting structure that is present on a substrate and/or device with which the DUT riser is configured to be in electrical communication.

When the aligning includes randomly and/or regularly aligning the plurality of electrical conduits, this may include aligning the plurality of electrical conduits such that they are spaced apart but at an average conduit pitch, or spacing, that is less than an average pad pitch, or spacing, of the electrical pad or other electrical contacting structure that is present on the substrate and/or device with which the DUT riser is configured to be in electrical communication. Additionally or alternatively, randomly and/or regularly aligning the plurality of electrical conduits also may include providing a plurality of electrical conduits that include an average diameter that is less than the average pad pitch and/or an average gap, or space, between adjacent pads. This may include electrical conduit diameters that are less than 75%, less than 70%, less than 60%, less than 50%, less than 40%, less than 30%, less than 25%, less than 20%, less than 15%, or less than 10% of the average pad pitch and/or the average gap between adjacent pads.

As discussed in more detail herein, the plurality of electrical conduits may be and/or include a metallic wire. When the plurality of electrical conduits includes a metallic wire, the aligning may include attaching the metallic wire to the substrate. Additionally or alternatively, and as also discussed in more detail herein, the plurality of electrical conduits may include a ferromagnetic wire. When the plurality of electrical conduits includes a ferromagnetic wire, the aligning may include applying a magnetic and/or electric field to the ferromagnetic wire. Applying the magnetic and/or electric field may include placing the plurality of electrical conduits between two planar surfaces and generating the magnetic and/or electric field between the two planar surfaces. When the plurality of electrical conduits includes the metallic wire, the metallic wire may be formed prior to performing the method.

As also discussed in more detail herein, the plurality of electrical conduits also may include a plurality of metallic bump pads that are in electrical communication with one another and which are operatively attached to one another to form a stack of metallic bump pads. When the plurality of electrical conduits includes the plurality of metallic bump pads, the aligning may include attaching a first metallic bump pad to the surface and subsequently attaching a second metallic bump pad to the first metallic bump pad. The attaching may be repeated until a length of the stack of metallic bump pads corresponds to a desired length of the metallic conduit.

As also discussed in more detail herein, the plurality of electrical conduits may be formed on the substrate. When the plurality of electrical conduits is formed on the substrate, the aligning may include depositing a conductive layer on the surface of the substrate and patterning the conductive layer to produce the plurality of electrical conduits. Illustrative, non-exclusive examples of depositing include physical vapor deposition, chemical vapor deposition, sputtering, evaporation, epitaxial growth, and/or plating. Illustrative, non-exclusive examples of patterning include lithographically defining a location of the plurality of electrical conduits and etching the conductive layer to produce and/or define the plurality of electrical conduits.

Encapsulating the plurality of electrical conduits in a dielectric material at 210 may include the use of any suitable system and/or method to coat, cover, surround, and/or otherwise encapsulate the plurality of electrical conduits with the dielectric material. It is within the scope of the present disclosure that the encapsulating may include encapsulating the plurality of electrical conduits without substantially disturbing a location of each of the plurality of electrical conduits.

As an illustrative, non-exclusive example, the encapsulating may include flowing the dielectric material on the surface of the substrate and around the plurality of electrical conduits. As another illustrative, non-exclusive example, the flowing may include placing an encapsulation dam on the surface of the substrate to constrain a flow of the dielectric material within a desired region, or portion, of the substrate prior to flowing the dielectric material. As another illustrative, non-exclusive example, the encapsulating also may include curing the dielectric material.

Performing steps 205 and 210 may produce a DUT riser, or at least a partially finished DUT riser, that may be present on the surface of the substrate. When the substrate includes an intermediate substrate, optionally removing the DUT riser from the surface of the intermediate substrate at 215 may include the use of any suitable systems and/or methods to remove the DUT riser from the surface. As illustrative, non-exclusive examples, the removing may include dissolving the intermediate substrate, dissolving a sacrificial and/or intermediate layer that forms the surface of the intermediate substrate, and/or physically separating the DUT riser from the intermediate substrate.

FIG. 6 is a flowchart depicting illustrative, non-exclusive examples of methods 300 according to the present disclosure of forming a DUT riser. Methods 300 may be broadly categorized as methods of forming a DUT riser, such as DUT riser 100, with such methods including the formation of voids within a matrix material prior to formation of the electrical conduits within the matrix material.

Methods 300 optionally include forming a solid body from a matrix material at 305. The methods further include forming a plurality of voids in the solid body at 310 and placing an electrically conductive material in the plurality of voids to form a plurality of electrical conduits at 315. The methods also may include optionally repeating the methods at 320, removing the matrix material from around the plurality of electrical conduits to form a plurality of unsupported electrical conduits at 325, encapsulating the plurality of unsupported electrical conduits in a dielectric material at 330, and/or removing the DUT riser from a substrate at 335.

Optionally forming the solid body at 305 may include forming a solid body that does not include the plurality of voids and/or forming the plurality of voids concurrently with forming the solid body. This may include forming the solid body on the surface of the substrate and/or forming the solid body as an independent body that is not present on and/or is removed from the surface of the substrate. As illustrative, non-exclusive examples, this may include flowing the matrix material onto the surface of a substrate, coating the matrix material onto the surface of the substrate, depositing the matrix material onto the surface of the substrate (including depositing using chemical vapor deposition, physical vapor deposition, evaporation, sputtering, screening, plating, and/or epitaxial growth), casting the matrix material, extruding the matrix material, molding the matrix material, and/or blowing the matrix material.

Matrix materials according to the present disclosure include any suitable material that may form the solid body, include and/or be made to include the plurality of voids that are discussed in more detail with reference to step 310, electrically insulate the plurality of electrical conduits formed at step 315 from one another, and/or be removed from around the plurality of electrical conduits without disturbing a location and/or orientation of the plurality of electrical conduits as discussed in more detail herein with reference to step 325. Illustrative, non-exclusive examples of matrix materials according to the present disclosure include dielectric materials, including the dielectric materials that are discussed in more detail herein. Additional illustrative, non-exclusive examples of matrix materials according to the present disclosure include materials that include a high etch selectivity relative to the material(s) that comprise the electrical conduits. As an illustrative, non-exclusive example, the electrical conduits may include gold, and the matrix material may include copper. As another illustrative, non-exclusive example, the electrical conduits may include a metal, and the matrix material may include photoresist and/or silicon oxides.

Forming the plurality of voids at 310 may include forming a plurality of voids that includes at least one hole and/or trench within the solid body. As an illustrative, non-exclusive example, the solid body may include a photoresist, and forming the plurality of voids may include lithographically forming and/or developing the plurality of voids. As another illustrative, non-exclusive example, forming the plurality of voids may include drilling the plurality of voids with a drill bit. As another illustrative, non-exclusive example, forming the plurality of voids may include ablating a portion of the solid body to form the plurality of voids. As an illustrative, non-exclusive example, the ablating may include laser ablating and/or electron beam ablating. As yet another illustrative, non-exclusive example, forming the plurality of voids may include etching away a portion of the solid body to form the plurality of voids, wherein a location of the plurality of voids optionally may be defined lithographically. As an illustrative, non-exclusive example, the etching may include chemical etching, wet etching, dry etching, and/or plasma etching.

Placing the electrically conductive material within the plurality of voids to form the plurality of electrical conduits at 315 may include the use of any suitable system and/or method to place, or position, the electrically conductive material. As illustrative, non-exclusive examples, and as discussed in more detail herein, the placing may include inserting the electrically conductive material into the plurality of voids, and such inserting may include inserting a metallic wire and/or a stack of metallic bump pads. As another illustrative, non-exclusive example, the placing may include depositing the electrically conductive material, and such depositing may include physical vapor deposition, chemical vapor deposition, screening, epitaxially growing, sputtering, and/or plating. When the solid body is present on the surface of a substrate, the placing also may include attaching the plurality of electrical conduits to the surface of the substrate and/or establishing electrical communication between the plurality of electrical conduits and the surface of the substrate and/or one or more electrical pads present on the surface of the substrate.

It is within the scope of the present disclosure that, prior to the placing, the method also may include coating at least one of a first surface of the solid body and a second surface of the solid body with a masking photoresist and patterning the masking photoresist. The masking photoresist may be configured to mask, or control, the portion(s) of the solid body that will come into contact with the electrically conductive material, thereby increasing process control, flexibility, and/or DUT riser reliability.

The patterning may include removing at least a portion of the masking photoresist that covers at least a portion of the plurality of voids. Subsequent to the depositing, the method also may include removing the masking photoresist from the solid body.

In some embodiments, the solid body of DUT riser 100 may not be present on, adhered to, and/or otherwise operatively attached to a substrate during the placing. Under these conditions, the solid body may include a first exposed surface that is in fluid communication with at least a portion of the plurality of voids, as well as a second exposed surface that is also in fluid communication with at least a portion of the plurality of voids. When the solid body includes the first and second exposed surfaces, the placing may include supplying at least a first portion of the electrically conductive material from a side of the DUT riser that includes the first exposed surface and/or supplying at least a second portion of the electrically conductive material from a side of the DUT riser that includes the second exposed surface. Supplying the conductive material to the voids present within the solid body from both the first surface and the second surface may decrease a distance that the electrically conductive material must travel within the voids prior to being deposited within the voids, decrease the effective aspect ratio of the voids for the supplying step due to the decreased distance, and/or increase a uniformity and/or reliability of the plurality of electrical conduits that are formed during the placing.

It is within the scope of the present disclosure that, prior to the placing, the methods also may include depositing an intermediate layer onto the solid body. When present, these intermediate layers may be configured to direct the placing within target, or desired, regions of the solid body, such as within the voids formed therein, increase adhesion between the solid body and the electrical conduits, improve the uniformity of the placing, and/or serve as a barrier layer to diffusion of the electrically conductive material into the solid body. Illustrative, non-exclusive examples of intermediate layers according to the present disclosure include a seed layer, a barrier layer, and a conductive layer. It is within the scope of the present disclosure that the depositing may include selectively depositing the intermediate layer. As an illustrative, non-exclusive example, the selectively depositing may include selectively depositing the intermediate layer within at least a portion of the plurality of voids and/or on a surface that defines at least a portion of the plurality of voids.

In some embodiments, the solid body may be present on, adhered to, and/or otherwise operatively attached to a substrate during the placing. Under these conditions, at least a portion of the plurality of voids may be in fluid communication with one or more conductive pads that may be present on a surface of the substrate. When the portion of the plurality of voids is in fluid communication with one or more conductive pads that are present on the surface of the substrate, the method also may include cleaning the portion of the plurality of pads, such as to remove a surface contaminant, prior to the placing. The cleaning may improve the reliability of the placing process, thereby improving the uniformity and/or reliability of the plurality of electrical conduits.

Repeating the method at 320 may include repeating each of step 305, 310, and 315 to increase the thickness of the DUT riser and/or the length of the plurality of the electrical conduits. When the method is repeated, forming the solid body from the matrix material at 305 may include forming a second, or subsequent, solid body on an upper surface of the DUT riser and/or attaching the solid body to the upper surface of the DUT riser. In addition, repeating the formation of the plurality of voids at 310 may include forming the plurality of voids within the second, or subsequent, solid body and/or forming the plurality of voids such that the plurality of voids is aligned and/or in fluid communication with a top surface of the plurality of electrical conduits. Similarly, placing the electrically conductive material into the plurality of voids at 315 may include placing the electrical conductive material into electrical communication with the plurality of electrical conduits, thereby increasing the length of the plurality of electrical conduits to form a plurality of composite, layered, and/or stacked pillars, or composite, layered, and/or stacked electrical conduits, that define the plurality of electrical conduits.

Removing the matrix material from around the plurality of electrical conduits to form a plurality of unsupported electrical conduits at 325 may include the use of any suitable system and/or method to remove the matrix material without damage to and/or disturbance of the plurality of electrical conduits. When the solid body was formed on the surface of a substrate, it is within the scope of the present disclosure that the plurality of electrical conduits may remain attached to and/or in electrical communication with the surface of the substrate when the matrix material is removed from the surface of the substrate. Illustrative, non-exclusive examples of processes and/or methods that may be utilized to remove the matrix material include etching and/or dissolution.

Encapsulating the plurality of unsupported electrical conduits at 330 may include the use of any suitable systems and/or methods to encapsulate the plurality of unsupported electrical conduits within the matrix material. Illustrative, non-exclusive examples of the encapsulating are discussed in more detail herein with reference to step 210 of FIG. 5.

When the solid body is present on the substrate during the placing, performing at least steps 310 and 315 may produce a DUT riser, or at least a partially finished DUT riser, that may be present on a surface of the substrate. When the substrate includes an intermediate substrate, optionally removing the DUT riser from the surface of the intermediate substrate at 335 may include the use of any suitable systems and/or methods to remove the DUT riser from the surface, including those discussed in more detail herein with reference to FIG. 5.

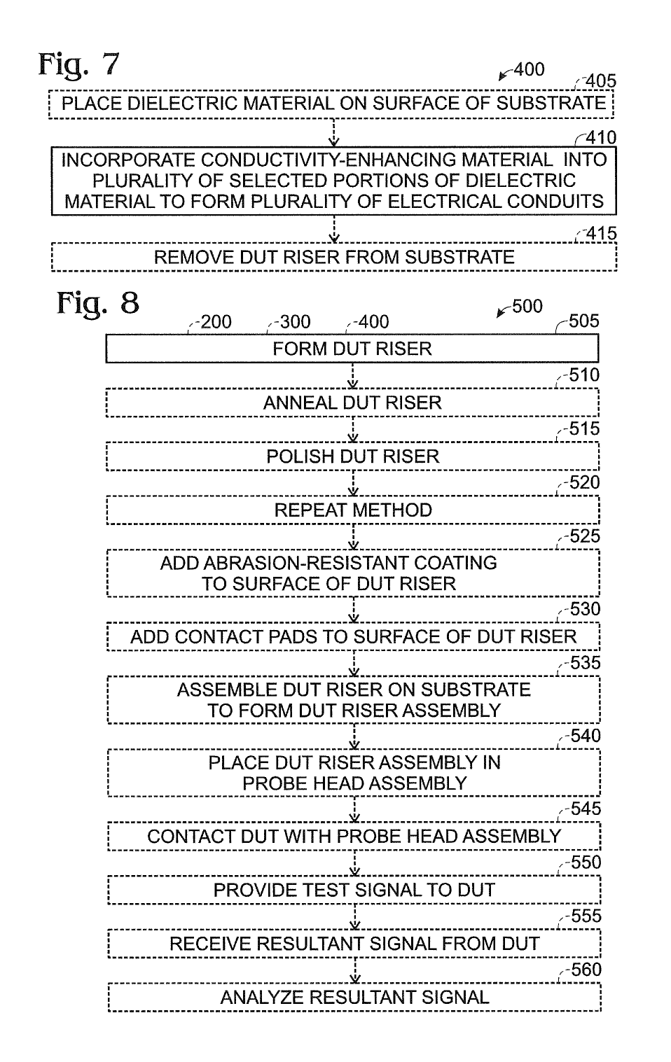

FIG. 7 is a flowchart depicting illustrative, non-exclusive examples of methods 400 according to the present disclosure of forming a DUT riser. Methods 400 may be broadly categorized as methods of forming a DUT riser, such as DUT riser 100, with such methods including the formation of the electrical conduits within the body of the DUT riser. Methods 400 optionally may include placing a dielectric material on a surface of a substrate at 405, and incorporating a conductivity-enhancing material into a plurality of selected portions of the dielectric material and/or changing the phase of the dielectric material to enhance the conductivity of the dielectric material and form a plurality of electrical conduits, as indicated at 410. The methods further optionally may include removing the DUT riser from the substrate, as indicated at 415.

Placing the dielectric material on the surface of the substrate at 405 may include the use of any suitable system and/or methods to form a layer of dielectric material on the surface of the substrate. Illustrative, non-exclusive examples of the placing include physical vapor deposition, chemical vapor deposition, evaporation, sputtering, spin-coating, laminating, dipping, and/or flowing.

The dielectric material may include any suitable material that may be made conductive through incorporation of the conductivity-enhancing material. Illustrative, non-exclusive examples of dielectric materials according to the present disclosure include a semiconductor material, silicon, gallium arsenide, germanium, chalcogenide glass, and/or a semiconducting polymer.

The conductivity-enhancing material may include any suitable material that may increase the conductivity of the dielectric material, thus providing for formation of the plurality of electrical conduits. An illustrative, non-exclusive example of conductivity-enhancing materials according to the present disclosure includes a dopant. When the conductivity-enhancing material includes a dopant, the incorporating may include implanting the dopant into, or otherwise locating the dopant within, the dielectric material.

As discussed in more detail herein with reference to FIGS. 5 and 6, the substrate may include an intermediate substrate. When the substrate includes an intermediate substrate, optionally removing the DUT riser, or partially formed DUT riser, from the substrate at 415 may include the use of any of the systems and methods that are discussed with reference to FIGS. 5 and 6.

FIG. 8 provides additional illustrative, non-exclusive examples of methods 500 of forming and/or using DUT risers (such as DUT risers 100) according to the present disclosure. Methods 500 include forming a DUT riser at 505 and optionally may include annealing the DUT riser at 510, polishing the DUT riser at 515, and/or repeating the method at 520. The methods 500 further optionally may include adding additional structure to the DUT riser, such as adding an abrasion-resistant coating to the DUT riser at 525 and/or adding contact pads to the DUT riser at 530. The methods also optionally may include assembling the DUT riser on a substrate to form a DUT riser assembly at 535 and/or placing the DUT riser assembly in a probe head assembly at 540. The methods further optionally may include using the probe head assembly to electrically test a device under test (DUT), which may include contacting the device under test with the probe head assembly at 545, providing a test signal to the device under test at 550, receiving a resultant signal from the device under test at 555, and/or analyzing the resultant signal at 560.

Forming the DUT riser at 505 may include forming a DUT riser according to the present disclosure using any suitable method. As illustrative, non-exclusive examples, the forming may include the use of methods 200, methods 300, and/or methods 400 that are discussed in more detail herein.

Annealing the DUT riser at 510 may include heating, baking, or otherwise curing the DUT riser. The annealing may include annealing to remove solvents from the DUT riser, increase a rigidity of the DUT riser, reduce a residual stress in the DUT riser, and/or provide dimensional stability to the DUT riser.

Polishing the DUT riser at 515 may include the use of any suitable polishing and/or lapping systems and/or methods. The polishing may include decreasing a thickness of the DUT riser, decreasing a length of at least a portion of the plurality electrical conduits that are present within the DUT riser, decreasing a surface roughness of the DUT riser, increasing a parallelism between a plane defined by a first surface of the DUT riser and a plane defined by a second surface of the DUT riser, and/or exposing an end of the plurality of electrical conduits that is proximal to at least one of the first surface of the DUT riser and the second surface of the DUT riser. The polishing may include polishing the first surface and/or the second surface of the DUT riser.

Repeating the method at 520 may include repeating any suitable portion, or portions, of the method. As an illustrative, non-exclusive example, the repeating may include repeating the method to increase the thickness of the DUT riser, the length of the plurality of electrical conduits that are included within the DUT riser, and/or the aspect ratio of the plurality of electrical conduits that are included within the DUT riser.

As another illustrative, non-exclusive example, the DUT riser may include an upper surface, and the repeating may include adding one or more additional DUT riser layers to the upper surface of the DUT riser to form a layered DUT riser structure including a plurality of layers, such as shown in the illustrative, non-exclusive example of FIG. 4. As yet another illustrative, non-exclusive example, the repeating may include adding a passive electronic component to the DUT riser such that the passive electronic component is present between two or more of the layers of the DUT riser. The repeating may include repeating the method any suitable number of times. As illustrative, non-exclusive examples, this may include repeating the method at least two, at least three, at least four, at least five, at least six, at least seven, at least eight, at least nine, or at least ten times.

Adding an abrasion-resistant coating at 525 may include the use of any suitable systems and/or methods to apply, deposit, or otherwise affix the abrasion-resistant coating to at least one surface of the DUT riser. Illustrative, non-exclusive examples of abrasion-resistant coatings according to the present disclosure include a coating of, and/or which includes, a dielectric material.

Adding contact pads to a surface of the DUT riser at 530 may include forming a plurality of contact pads on one or more surfaces of the DUT riser. As discussed in more detail herein, the plurality of contact pads may be in electrical communication with the plurality of electrical conduits that are included in the DUT riser, and the plurality of contact pads may provide a robust, durable, chemically inert, and/or systematically located surface for forming an electrical contact between the DUT riser and one or more other devices that may be in electrical communication with the DUT riser.

The plurality of contact pads may be present on one or both ends of at least a portion, and optionally all, of the plurality of electrical conduits. Forming the plurality of contact pads may include forming an adhesion layer on a surface of the DUT riser, lithographically defining a location of the plurality of contact pads, etching the adhesion layer to define a plurality of conductive bases, electroplating the plurality of conductive bases to form the plurality of contact pads, and/or capping the plurality of contact pads. The capping may include coating the plurality of contact pads with a coating material, such as an abrasion-resistant coating material and/or a corrosion-resistant coating material. As an illustrative, non-exclusive example, the capping may include electroplating the plurality of contact pads with a noble metal, hard gold, ruthenium, osmium, iridium, diamond-like carbon, and/or rhodium.

Assembling the DUT riser on a substrate at 535 may include the use of any suitable systems and/or methods to assemble, attach, and/or place the DUT riser into electrical communication with the substrate. As an illustrative, non-exclusive example, the assembling may include establishing electrical communication between the plurality of electrical conduits and a plurality of electrical pads that are located on the substrate.

As an illustrative, non-exclusive example, establishing electrical communication may include using a conductive adhesive to adhere a portion of each of the electrical contacts and/or a contact pad that is in electrical communication therewith to an associated, or complementarily located, electrical pad that is present on the substrate with a conductive adhesive. As an additional illustrative, non-exclusive example, the establishing electrical communication may include soldering the portion of each of the electrical contacts to the associated electrical pads. As yet another illustrative, non-exclusive example, the establishing also may include depositing a heat-curing dielectric onto the substrate, removing a portion of the heat-curing dielectric to expose the plurality of electrical pads present on the surface of the substrate, replacing the removed portion of the heat-curing dielectric with a heat-curing electrically conductive adhesive, pressing the DUT riser into contact with the heat-curing dielectric and the heat-curing electrically conductive adhesive to form a DUT riser assembly, and/or heating the DUT riser assembly to cure the heat-curing dielectric and the heat-curing electrically conductive adhesive.

As yet another illustrative, non-exclusive example, establishing electrical communication also may include forming a plurality of contact structures, such as rocking beam interposers, that are in electrical communication with the plurality of electrical conduits on a surface of the DUT riser. The establishing further may include encapsulating the plurality of contact structures in a heat-setting resin, pressing the plurality of contact structures into electrical contact with the plurality of electrical pads on the substrate to form a DUT riser assembly that includes an electrical connection between the plurality of electrical conduits and the plurality of electrical pads, and/or heating the DUT riser assembly to cure the heat-setting resin.

As yet another illustrative, non-exclusive example, the assembling further may include backfilling a space between the DUT riser and the substrate with a dielectric material. The backfilling may serve to seal and/or attach the DUT riser to the substrate and/or to decrease a potential for corrosion and/or separation of the electrical contacts between the DUT riser and the substrate.

Placing the DUT riser assembly in a probe head assembly at 540 may include the use of any suitable systems and/or methods to construct or configure a probe head assembly that includes the DUT riser. As illustrative, non-exclusive examples, this may include placing the DUT riser assembly in a probe head assembly, or portion thereof, as shown in FIGS. 1-2.

Contacting a DUT with the probe head assembly at 545 may include bringing a DUT-contacting portion of the probe head assembly into electrical communication with the DUT. This may include physically moving the DUT into electrical contact with the probe head assembly and/or physically moving the probe head assembly into electrical contact with the DUT.

Providing the test signal to the DUT from the probe heat assembly at 550, receiving the resultant signal from the DUT with the probe head assembly at 555, and/or analyzing the resultant signal at 560 may include the use of any suitable systems and/or methods to provide the test signal, receive the resultant signal, and/or analyze the resultant signal. As an illustrative, non-exclusive example, the providing, receiving, and analyzing may be performed by the test system of FIG. 1.

FIGS. 9-44 provide illustrative, non-exclusive examples of complete DUT risers, portions of DUT risers, DUT riser assemblies, and/or process flows that may be utilized in the creation of DUT riser assemblies according to the present disclosure. The examples provided in FIGS. 9-44 are more specific, but still illustrative, non-exclusive examples of the systems, DUT risers 100, and methods that are described in FIGS. 1-8.

FIGS. 9-13 provide an illustrative, non-exclusive example of a process flow that may be utilized to create a DUT riser 100 that includes a plurality of electrical conduits 110 in the form of a plurality of stacked metallic bump pads 112. In FIG. 9, a first stack of metallic bump pads 112 may be formed on each of a plurality of electrical pads 92 that are present on a surface of substrate 90. In FIG. 10, an encapsulation dam 160 may be placed on an upper surface 94 of substrate 90, and a liquid dielectric material 107 may be provided to a space defined by encapsulation dam 160 to encapsulate the plurality of electrical conduits 110. The liquid dielectric material subsequently is cured to produce a solid dielectric material 108. In FIG. 11, DUT riser 100 has been polished, thereby decreasing a thickness 144 of the DUT riser and exposing an upper surface 164 of the plurality of electrical conduits 110.

As discussed in more detail herein, the DUT riser of FIG. 11 may receive additional processing, such as through the addition of one or more contact pads to the DUT riser, removal of the DUT riser from substrate 90, and/or assembly and/or use of the DUT riser within a probe head assembly. Additionally or alternatively, and as also discussed in more detail herein, the method may be repeated to increase thickness 144 of the DUT riser, as shown in FIGS. 12-13. In FIG. 12, a second DUT riser layer 152 may be formed on top of a previously formed first DUT riser layer 151. This may include forming a second layer, or stack, of metallic bump pads 112 on top of the first layer, or stack, of metallic bump pads 112, a second encapsulation dam 160 may be placed above the first encapsulation dam 160, and a second layer of liquid dielectric material 107 may be flowed above first solid dielectric material 108 to encapsulate the plurality of electrical conduits 110. The second layer of liquid dielectric material may be subsequently cured to produce solid dielectric material 108.

As shown in FIG. 13, DUT riser 100 may once again be polished to produce a final DUT riser thickness 144 and/or expose upper surfaces 164 of electrical conduits 110. Once again, the DUT riser of FIG. 13 optionally may receive additional processing, as discussed in more detail herein, and/or a third, and/or subsequent, layer may be added to the DUT riser by repeating the previous steps.

FIGS. 14-16 provide illustrative, non-exclusive examples of a process flow that may be utilized to produce contact pads 130 on DUT riser 100. In the illustrative, non-exclusive examples of FIGS. 14-16, DUT riser 100 includes a two-layer DUT riser 100 (i.e., DUT riser 100 with two layers 150) and electrical conduits 110 include a plurality of metallic bump pads 112. However, it is within the scope of the present disclosure that the process flow of FIGS. 14-16 may be utilized to produce contact pads on a DUT riser that includes any suitable number of layers, including one layer, two layers, three layers, or more than three layers, and/or any suitable type of DUT riser electrical conduit 110.

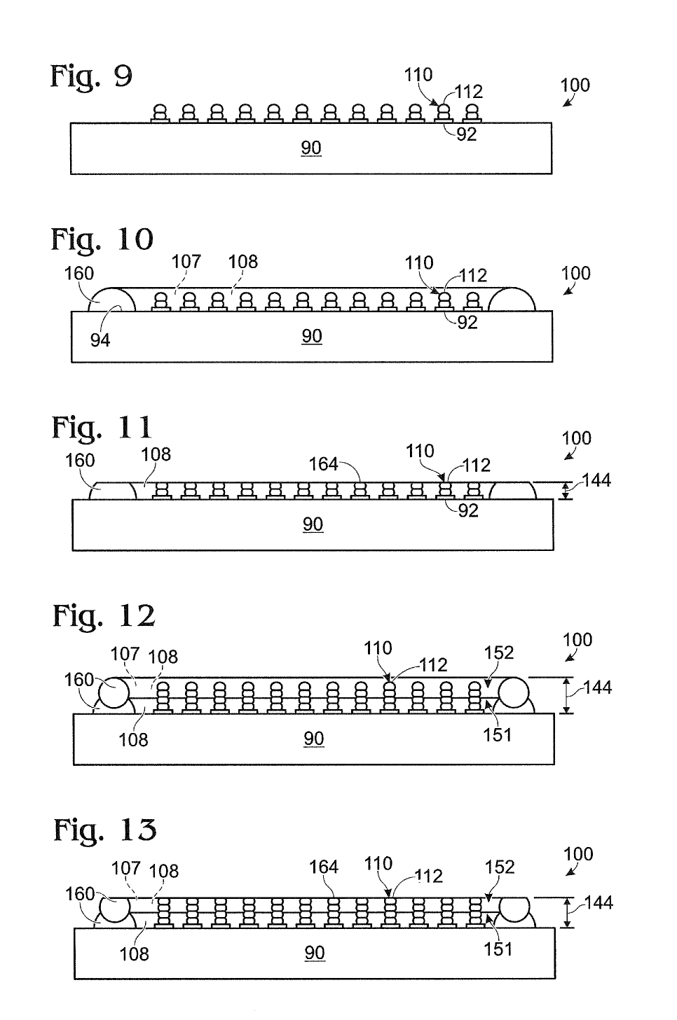

FIG. 14 shows a close-up view of a portion of a DUT riser 100 that may be similar to the DUT riser of FIG. 13. In FIG. 15, an adhesion layer 168 has been added to an upper surface 170 of the DUT riser, and a plurality of contact pads 130 has been defined on the upper surface of the DUT riser. In the illustrative, non-exclusive example of FIG. 15, the contact pads may be defined by depositing a metallic layer on the upper surface of the DUT riser, lithographically patterning the metallic layer, and etching the metallic layer to produce the plurality of contact pads 130. However, any other suitable method may be utilized to produce the contact pads, including the plating process flow that is discussed in more detail herein.

After creation of the plurality of contact pads, the contact pads may be capped with a coating material to form an abrasion-resistant surface, or coating, 138, and adhesion layer 168 may be removed from the space between the contact pads to electrically isolate the contact pads from one another. This is shown schematically in FIG. 16.

FIGS. 15-16 also schematically illustrate that, as discussed in more detail herein, contact pads 130 may not be aligned and/or centered over electrical conduits 110. Instead, contact pads 130 may be aligned, centered, and/or registered such that their location corresponds to a location of another electrical contact, such as electrical pad 92, that may be on and/or form a portion of a substrate, another contact pad 130 that is located on an opposed surface of the DUT riser, and/or a corresponding electrical pad on the device under test.

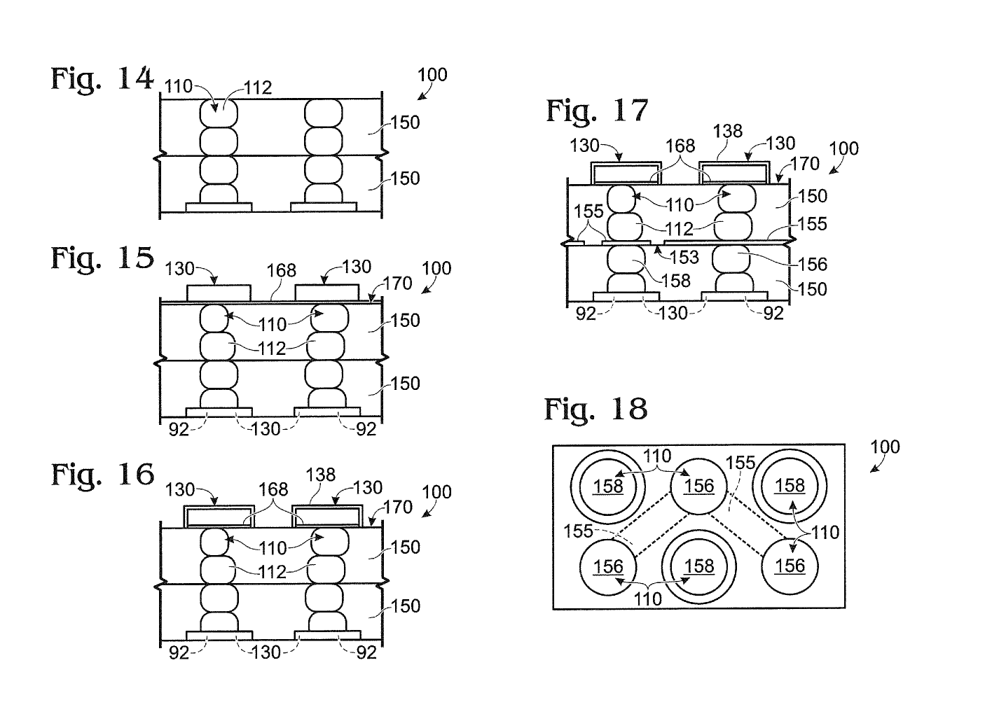

FIGS. 17-18 illustrate that, as discussed in more detail herein, DUT risers 100 according to the present disclosure may include one or more passive electronic components 155 between two or more layers 150 thereof. Passive electronic components 155 may be configured to electrically connect two or more electrical conduits 110 of the DUT riser.

FIG. 17 provides a cross-sectional view of a DUT riser 100 that includes passive electronic components 155, while FIG. 18 provides a top view of a similar DUT riser. FIGS. 17 and 18 illustrate that power supply conduits 158 may be electrically isolated from the other electrical conduits present within DUT riser 100, while ground conduits 156 may be electrically interconnected to form a common ground plane within the DUT riser. Similar to the illustrative, non-exclusive examples of FIGS. 14-16, the passive electronic components illustrated in FIGS. 17-18 may be utilized with any suitable electrical conduit construction and/or with a DUT riser that includes any suitable number of layers. When the DUT riser includes three or more layers, a plurality of interfacial regions 153 between layers 150 may include passive electronic components 155.

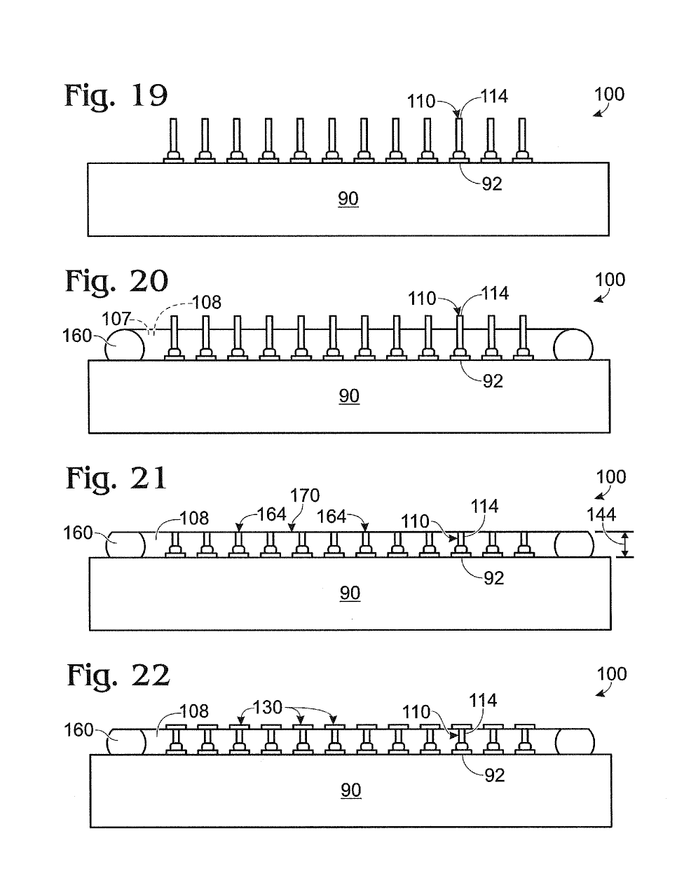

FIGS. 19-22 provide an illustrative, non-exclusive example of a process flow that may be utilized to create a DUT riser 100 that includes a plurality of electrical conduits 110 in the form of a plurality of metallic wires 114. The process flow of FIGS. 19-22 is substantially similar to the process flow that was discussed in more detail herein with reference to FIGS. 9-13.

In FIG. 19, a plurality of electrical conduits 110, in the form of a plurality of metallic wires 114, are attached to a plurality of electrical pads 92 that are present on a substrate 90. In FIG. 20, an encapsulation dam 160 constrains a flow of a liquid dielectric material 107 as it is applied to the surface of the substrate. The liquid dielectric material is subsequently cured to produce a solid dielectric material 108.

The DUT riser may then be polished, as shown in FIG. 21, to produce a desired DUT riser thickness 144 and/or to ensure that an upper surface 164 of electrical conduits 110 is at least substantially coplanar with an upper surface 170 of DUT riser 100. Prior to proceeding to the optional formation of contact pads 130 on upper surface 170 of the DUT riser, as shown in FIG. 22, the steps of FIGS. 19-21 optionally may be repeated to increase the thickness of the DUT riser. In addition, and as discussed in more detail herein, the DUT riser may be removed from substrate 90 subsequent to formation thereof.

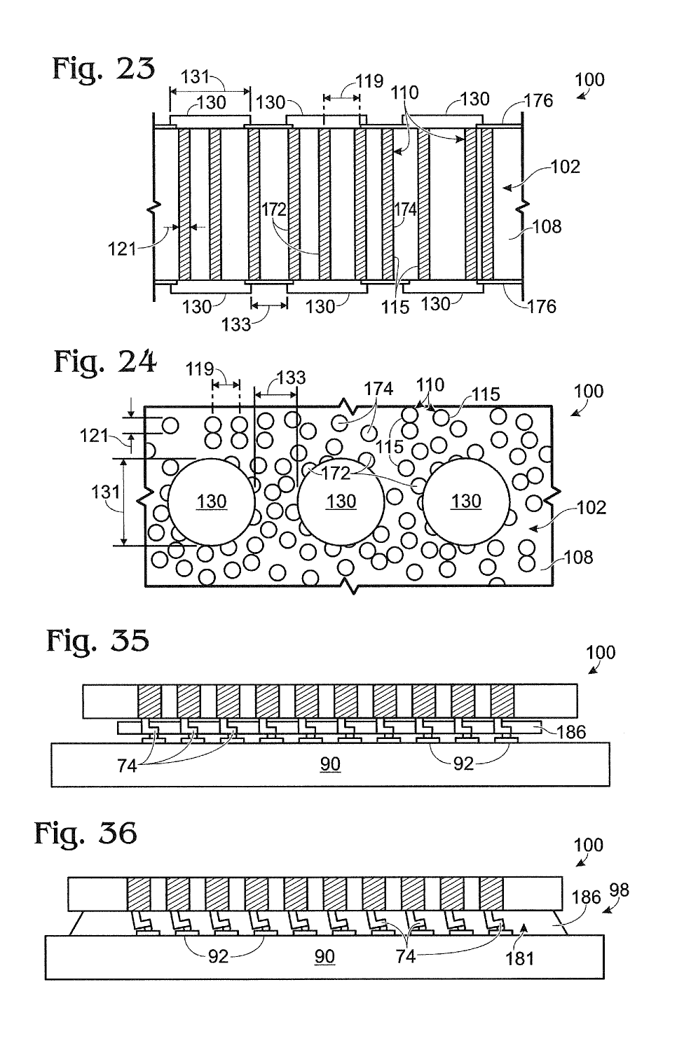

FIGS. 23 and 24 provide an illustrative, non-exclusive example of a DUT riser 100 that includes a plurality of electrical conduits 110 in the form of a random distribution of ferromagnetic wires 115, which also may be referred to herein as ferromagnetic pillars 115, contained within a body 102 that includes a solid dielectric material 108. FIG. 23 is a schematic cross-sectional view of the DUT riser, while FIG. 24 is a schematic top or bottom view of the DUT riser. Due to the random arrangement of ferromagnetic wires 115, the DUT riser of FIGS. 23-24 includes a plurality of ferromagnetic wires that are in electrical contact with contact pads 130, as indicated at 172, as well as a plurality of ferromagnetic wires that are not in electrical contact with contact pads 130, as indicated at 174. The DUT riser also may include an abrasion-resistant coating 176 on at least one surface thereof.

As discussed in more detail herein, the DUT riser of FIGS. 23 and 24 may be formed by aligning the plurality of ferromagnetic wires 115 between two parallel surfaces through the application of a magnetic field to the plurality of ferromagnetic wires and encapsulating the plurality of ferromagnetic wires in a liquid dielectric material. The liquid dielectric material may be subsequently cured to produce solid dielectric material 108. Subsequently, contact pads 130 and/or abrasion-resistant coating 176 may be formed on one or more surfaces of the DUT riser, as also discussed in more detail herein.

FIGS. 23-24 further illustrate that, as also discussed in more detail herein, an average spacing 119 between individual ferromagnetic wires 115 of the DUT riser, such as between the longitudinal axes thereof, may be less than an average characteristic dimension 131 of contact pads 130. This average spacing, or gap, between the ferromagnetic wires may be controlled to provide for construction of a DUT riser in which each contact pad 130 is, or is on average, in electrical communication with at least one, at least two, at least three, at least four, at least five, at least seven, or at least ten ferromagnetic wires 115. Furthermore, FIGS. 23-24 also illustrate that a diameter 121, or other characteristic cross-sectional dimension, of ferromagnetic wires 115 may be less than the average spacing, or gap, 133 between contact pads 130. This may provide for construction of a DUT riser 100 in which individual contact pads 130 are not shorted together by a ferromagnetic wire that bridges the gap between the contact pads.

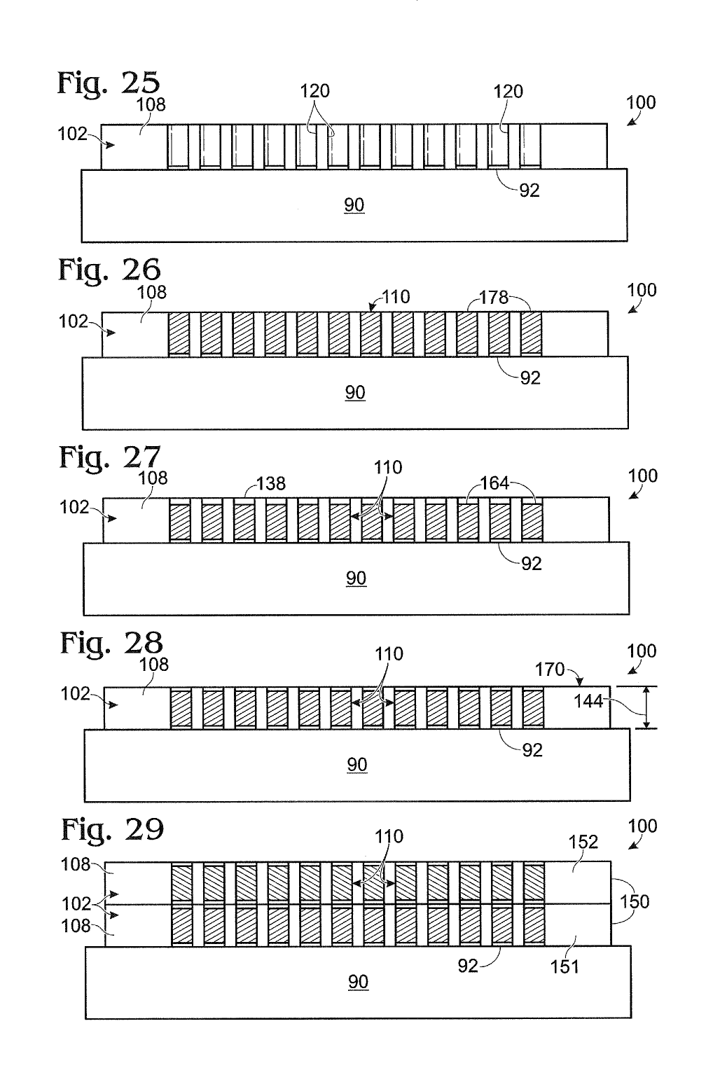

FIGS. 25-29 provide an illustrative, non-exclusive example of a process flow that may be utilized to create a DUT riser 100 that may include a plurality of electrical conduits 110 (as shown in FIGS. 26-27) that may be placed into a void 120 present within dielectric material 108 of body 102. In FIG. 25, a plurality of voids 120 have been formed in body 102 above a plurality of electrical contacts 92 that are present on a surface of substrate 90. The plurality of voids may be formed in any suitable manner, including the illustrative, non-exclusive examples of void formation methods that are discussed in more detail herein.

In FIG. 26, an electrically conductive material 178 has been placed within the voids to form a plurality of electrical conduits 110. In FIG. 27, an upper surface 164 of the electrical conduits has been capped with a coating material to form abrasion-resistant surface, or coating, 138, which may increase the durability and/or corrosion resistance of electrical conduits 110. In FIG. 28, an upper surface 170 of the DUT riser has been polished to produce a target DUT riser thickness 144. Additionally or alternatively, and as shown in FIG. 29, the process flows of FIGS. 25-26 may be repeated to produce a layered DUT riser that includes a plurality of layers 150, including at least first layer 151 and second layer 152, prior to the capping (as shown in FIG. 27) and/or the polishing (as shown in FIG. 28).

Electrically conductive material 178 may be placed into voids 120 using any suitable method, illustrative, non-exclusive examples of which are discussed in more detail herein. As also discussed in more detail herein, DUT riser 100 may be removed from substrate 90 subsequent to formation thereof.

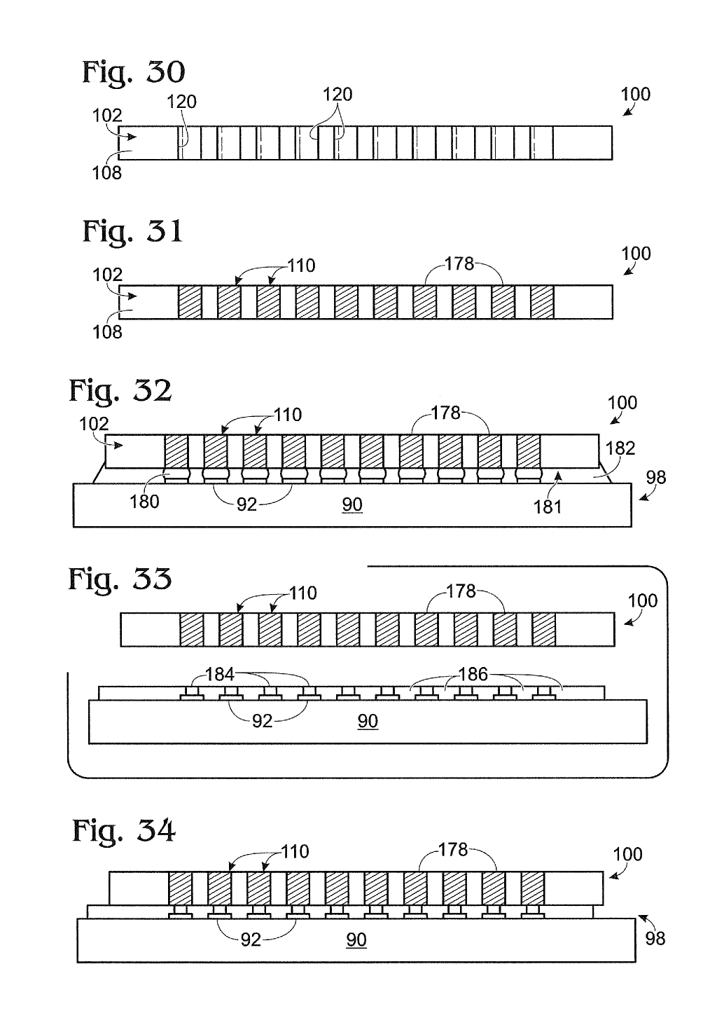

FIGS. 30-31 provide another illustrative, non-exclusive example of a process flow that may be utilized to create a DUT riser 100 that is not formed on a substrate. In FIG. 30, body 102, including solid dielectric material 108, may include a plurality of voids 120 that may be formed using any suitable method, illustrative, non-exclusive examples of which are discussed in more detail herein.

In FIG. 31, the voids have been filled with an electrically conductive material 178 to form electrical conduits 110. Electrical conduits 110 may be formed in any suitable manner, illustrative, non-exclusive examples of which are discussed in more detail herein. Subsequent to forming the electrical conduits, DUT riser 100 may receive further processing. As an illustrative, non-exclusive example, contact pads and/or an abrasion-resistant coating may be formed on the DUT riser, as discussed in more detail herein.

FIG. 32 is an illustrative, non-exclusive example of a DUT riser 100 that is assembled on a substrate 90 such that the DUT riser is in electrical communication with, and operatively attached to, the substrate to form a DUT riser assembly 98. The DUT riser assembly of FIG. 32 may be constructed using a C4 process in which a plurality of solder bumps 180 may be placed between electrical conduits 110 of DUT 100 and electrical pads 92 of substrate 90. Subsequent to placing the solder bumps, the DUT riser may be pressed into contact with the substrate, and the assembly may be heated, causing the solder bumps to flow, and forming an electrical and physical connection between DUT riser 100 and substrate 90. Subsequent to flowing the solder bumps, a backfill material 182, such as a dielectric material, may be provided to a region 181 between DUT riser 100 and substrate 90 to seal and/or attach the DUT riser to the substrate and/or to decrease a potential for corrosion and/or separation of solder bumps 180.

FIGS. 33-34 provide an illustrative, non-exclusive example of a process flow that may be utilized to assemble a DUT riser 100 on a substrate 90 such that the DUT riser is in electrical communication with, and operatively attached to, the substrate to form a DUT riser assembly 98. In FIG. 33, substrate 90 includes a plurality of electrical pads 92. Each of the plurality of electrical pads is coated, or otherwise covered, by a heat-curing electrically conductive adhesive 184, while a space between the plurality of electrical pads is coated, or otherwise covered, by a heat-curing dielectric adhesive 186. Illustrative, non-exclusive examples of methods of coating the substrate with dielectric adhesive 186 and/or electrically conductive adhesive 184 are discussed in more detail herein. In FIG. 34, DUT riser 100 and substrate 90 have been pressed together and heated, thereby curing heat-curing adhesives 184/186 and creating DUT riser assembly 98.

FIGS. 35-36 provide another illustrative, non-exclusive example of a process flow that may be utilized to assemble a DUT riser 100 on a substrate 90 such that the DUT riser is in electrical communication with and operatively attached to the substrate to form a DUT riser assembly 98 (as illustrated in FIG. 36). In FIGS. 35-36, a plurality of rocking beam interposers 74 may be surrounded by a heat-curing dielectric adhesive 186, or another heat-curing resin 186, and may form a plurality of electrical connections between DUT riser 100 and electrical pads 92 of substrate 90. Application of pressure to the DUT riser assembly may deflect the plurality of rocking beam interposers, thereby deflecting the plurality of rocking beam interposers 74 (as illustrated in FIG. 36) and producing a scrubbing action in a contact region between the rocking beam interposers and electrical pads 92 of substrate 90. This scrubbing action may increase a reliability of electrical contact therebetween. Application of heat to the DUT riser assembly may cure the heat-curing dielectric adhesive, thereby fixing the rocking beam interposers in place and providing a robust physical attachment between the DUT riser and the substrate, as illustrated in FIG. 36.

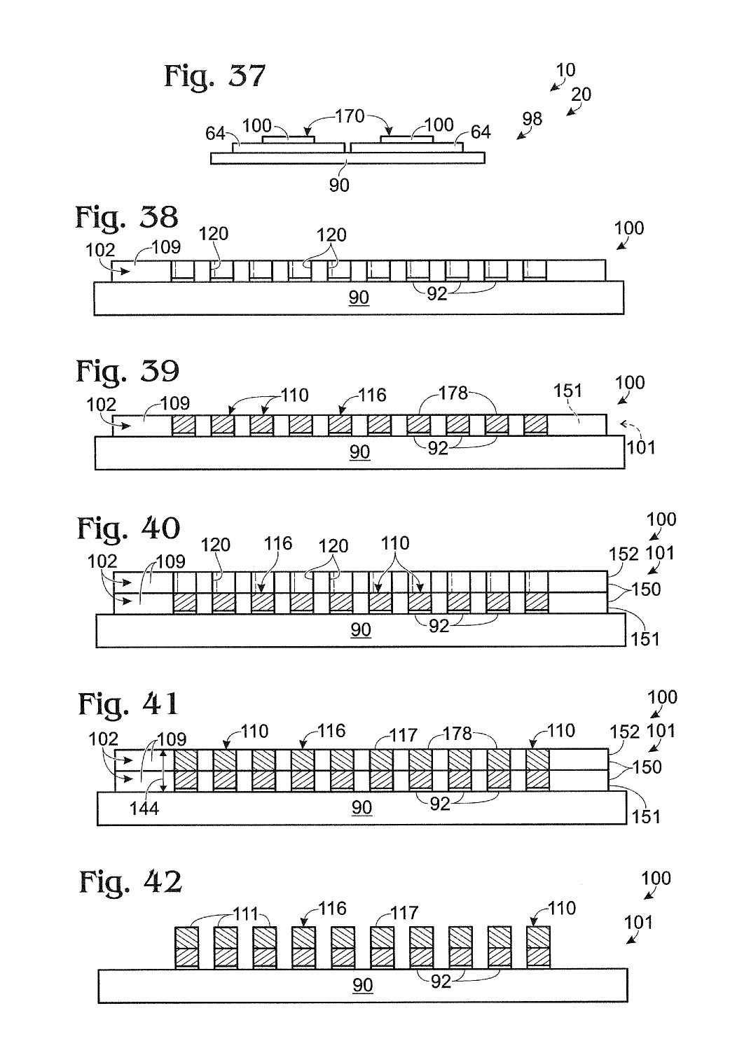

FIG. 37 provides an illustrative, non-exclusive example of a DUT riser assembly 98 that includes a plurality of space transformers 64 and a plurality of DUT risers 100 assembled on a single substrate 90. The DUT riser assembly of FIG. 37 may be utilized as part of a probe head assembly 20 and/or a test system 10 to electrically test the performance and/or operation of a plurality of devices under test with a single probe head assembly. The use of a plurality of DUT risers 100 according to the present disclosure may provide for precise alignment of upper (or top) surfaces 170 of the DUT risers in a similar, or at least substantially similar, plane. As an illustrative, non-exclusive example, the plurality of DUT risers 100 may be assembled on substrate 90 prior to polishing the plurality of DUT risers to their final thickness, and the polishing may align upper surfaces 170 in an at least substantially similar plane.

While a DUT riser assembly 98 that includes a single substrate and two DUT risers is shown in FIG. 37, it is within the scope of the present disclosure that DUT riser assembly 98 may include any suitable number of DUT risers, including two, three, four, five, six, seven, eight, nine, ten, or more than ten DUT risers. In addition, the DUT riser assembly may be assembled in a probe head that is configured to electrically probe, or test, any suitable type and/or number of devices under test. As an illustrative, non-exclusive example, the device under test may include a plurality of singulated die, and the DUT riser assembly may include a separate DUT riser for each of the plurality of singulated die. As another illustrative, non-exclusive example, the device under test may include a single die that may be contacted during electrical testing in a plurality of locations, and the DUT riser assembly may include a separate DUT riser for each of the plurality of locations.

FIGS. 38-44 provide an illustrative, non-exclusive example of a process flow that may be utilized to create a DUT riser 100 that includes a plurality of electrical conduits 110 in the form of a plurality of deposited electrical conduits 116, which also may be referred to herein as deposited electrical pillars 116, and/or composite, layered, and/or stacked, pillars 117 (as illustrated in FIG. 44). In FIG. 38, a solid body 102, such as a matrix material 109, has been deposited on a substrate 90 and a plurality of voids 120 have been formed within the matrix material above a plurality of electrical pads 92 present on an upper surface of the substrate. In FIG. 39, a plurality of electrical conduits 110, in the form of a plurality of deposited electrical conduits 116, have been formed and/or placed within voids 120 through deposition of an electrically conductive material 178 within the voids.

DUT riser 100 of FIG. 39 may be a completed DUT riser that is substantially similar to the DUT riser of FIGS. 25-29. Alternatively, DUT riser 100 of FIG. 39 may include and/or be a first layer 151 of a layered, stacked, and/or composite DUT riser 101 that includes a plurality of layers 150, as shown in FIG. 40. When the DUT riser includes layered DUT riser 101, one or more additional layers of matrix material 102 may be added to the DUT riser to form the layered structure. Thus, the DUT riser of FIG. 40 includes first layer 151, as well as a second layer 152 of matrix material 102 and/or DUT riser 101. In FIG. 40, second layer 152 includes a plurality of voids 120 that are above electrical conduits 110 of first layer 151.

In FIG. 41, the voids have been filled with an additional layer of conductive material 178 to increase the length of electrical conduits 110 and/or deposited electrical conduits 116. Thus, the electrical conduits now include two layers and may be referred to herein as composite, layered, and/or stacked pillars 117 and/or as composite, layered, and/or stacked electrical conduits 117. The process steps of FIGS. 40 and 41 may be repeated as desired to produce layered pillars 117 of a target, or desired, length and/or layered DUT risers 101 of a target, or desired, thickness 144.

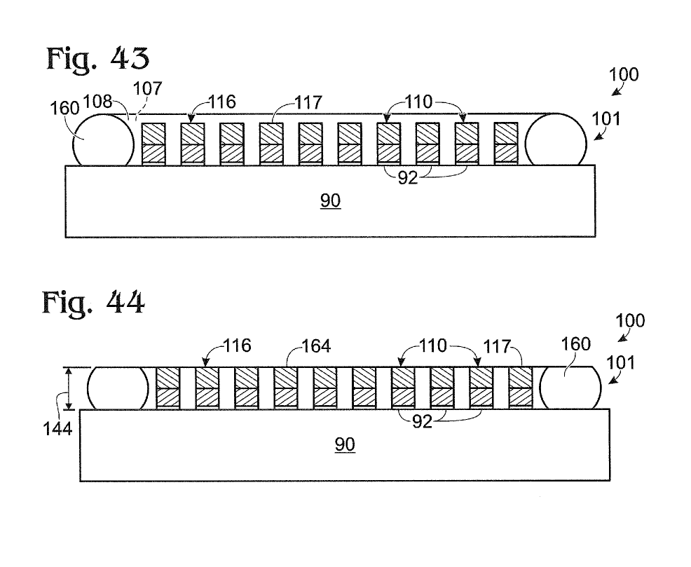

Once the target thickness has been reached, matrix material 109 may be removed from the partially completed DUT riser to produce a plurality of unsupported electrical conduits 111, which also may be referred to herein as unsupported electrical pillars 111, as shown in FIG. 42. As shown in FIG. 43, the plurality of unsupported electrical conduits 111 may be encapsulated in a solid dielectric material 108 using any of the systems and methods discussed in more detail herein.

This encapsulation may include the use of an encapsulation dam 160 to control a flow of a liquid dielectric material 107 that may applied to substrate 90 to cover unsupported electrical conduits 111. Subsequent to the encapsulation, the layered DUT riser may be polished to produce a final, or desired, thickness 144 of the DUT riser and/or to expose upper surfaces 164 of layered electrical conduits 117 as shown in FIG. 44. In addition, it is also within the scope of the present disclosure that the upper surface of DUT riser 100 may be polished subsequent to performing any of the process steps that are presented herein. The polishing may be performed for any suitable reason and/or based on any suitable criteria, illustrative, non-exclusive examples of which include planarizing the surface of the DUT riser, decreasing the thickness of the DUT riser, and/or decreasing a surface roughness of the DUT riser.

The systems and methods disclosed herein have been described with reference to a DUT riser that is configured to provide electrical communication between a first side of the DUT riser and a second side of the DUT riser, as well as to DUT riser assemblies, probe heads, and/or test systems that may utilize the DUT riser to transfer a plurality of electrical signals. It is within the scope of the present disclosure that the systems and methods disclosed herein also may be utilized to transmit optical signals and/or perform optical testing of an optical device. Thus, the words electric, electrical, electrically, and/or electronic may be replaced with the words optic, optical, and/or optically without departing from the scope of the present disclosure. Similarly, references to the word dielectric may be replaced with the word opaque and/or the phrase “non-optically conducting” and references to the phrase “electric current” may be replaced by the phrase “optical signal” without departing from the scope of the present disclosure. Furthermore, illustrative, non-exclusive examples of passive optical components according to the present disclosure include any suitable reflective surface, waveguide, fiber optic device, and/or lens.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently. It is also within the scope of the present disclosure that the blocks, or steps, may be implemented as logic, which also may be described as implementing the blocks, or steps, as logics. In some applications, the blocks, or steps, may represent expressions and/or actions to be performed by functionally equivalent circuits or other logic devices. The illustrated blocks may, but are not required to, represent executable instructions that cause a computer, processor, and/or other logic device to respond, to perform an action, to change states, to generate an output or display, and/or to make decisions.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entity in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” may mean A alone, B alone, C alone, A and B together, A and C together, B and C together, A, B and C together, and optionally any of the above in combination with at least one other entity.

As used herein, the term “may” indicates that a given structure, component, feature, and/or process step is optional to, but not required in, a given embodiment. This includes variations of the given embodiment that include a portion, a majority, and/or all of the structures, components, features, and/or process steps disclosed as optionally being associated with the given embodiment, as well as variations of the given embodiment that do not include any of the structures, components, features, and/or process steps disclosed as optionally being associated with the given embodiment. In addition, inclusion of a first optional structure, component, feature, and/or process step in a given embodiment does not require or preclude inclusion of a second optional structure, component, feature, and/or process step in the given embodiment.

In the event that any patents, patent applications, or other references are incorporated by reference herein and define a term in a manner or are otherwise inconsistent with either the non-incorporated portion of the present disclosure or with any of the other incorporated references, the non-incorporated portion of the present disclosure shall control, and the term or incorporated disclosure therein shall only control with respect to the reference in which the term is defined and/or the incorporated disclosure was originally present.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

Illustrative, non-exclusive examples of systems and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. An interposer comprising:

a substantially planar body, wherein the body includes a first surface and a second surface that is at least substantially opposed to the first surface, and further wherein the body includes a solid dielectric material; and

a plurality of electrical conduits contained within the body and configured to conduct a plurality of electric currents between the first surface and the second surface.

A2. The interposer of paragraph A1, wherein the body is formed around the plurality of electrical conduits, and optionally wherein the body is formed after the plurality of electrical conduits.

A3. The interposer of any of paragraphs A1-A2, wherein the plurality of electrical conduits includes a plurality of metallic bump pads that are at least one of in electrical communication with one another and stacked on top of one another to form a stack of metallic bump pads.

A4. The interposer of paragraph A3, wherein the plurality of metallic bump pads are added to the plurality of electrical conduits in a sequential fashion to increase a length of the plurality of electrical conduits.

A5. The interposer of any of paragraphs A3-A4, wherein the plurality of metallic bump pads has a continuous, nonlinear, and substantially periodic longitudinal cross sectional shape.

A6. The interposer of any of paragraphs A3-A5, wherein the plurality of metallic bump pads has a substantially circular transverse cross-sectional shape.

A7. The interposer of any of paragraphs A1-A2, wherein the plurality of electrical conduits includes a metallic wire.

A8. The interposer of paragraph A7, wherein the metallic wire is formed separately from and placed within the interposer.

A9. The interposer of any of paragraphs A7-A8, wherein the metallic wire is at least one of randomly, regularly, and systematically located within the solid dielectric material.

A10. The interposer of any of paragraphs A1-A2, wherein the plurality of electrical conduits includes a deposited electrical conduit, and optionally wherein the deposited electrical conduit includes a composite pillar of electrically conductive material that is formed in a plurality of layers.

A11. The interposer of paragraph A10, wherein the deposited electrical conduit is formed by at least one of physical vapor deposition, chemical vapor deposition, evaporation, epitaxial growth, and plating.

A12. The interposer of any of paragraphs A10-A11, wherein a shape and a location of the deposited electrical conduit is defined by at least one of a lithographic process and an etching process.

A13. The interposer of any of paragraphs A1-A12, wherein the plurality of electrical conduits includes a metallic conduit that is formed within a void present within the solid dielectric material, and optionally wherein the metallic conduit is at least one of deposited and plated within the void.

A14. The interposer of paragraph A13, wherein the void is formed by at least one of etching, mechanical drilling, laser drilling, and lithography.

A15. The interposer of any of paragraphs A1-A14, wherein the plurality of electrical conduits includes a conductive region that is incorporated into the solid dielectric material.

A16. The interposer of paragraph A15, wherein the conductive region includes a dopant that is implanted into the solid dielectric material.

A17. The interposer of any of paragraphs A1-A16, wherein the plurality of electrical conduits includes at least one of a metal, copper, a copper alloy, gold, a gold alloy, one or more carbon nanotubes, graphene, and a doped semiconductor material.

A18. The interposer of any of paragraphs A1-A17, wherein the interposer further includes a plurality of contact pads, wherein at least a portion of the plurality of contact pads is in electrical communication with at least one of the plurality of electrical conduits and is located on at least one of the first surface and the second surface.

A19. The interposer of paragraph A18, wherein the plurality of contact pads includes a first contact pad in electrical communication with a selected one of the plurality of electrical conduits and located on the first surface, and a second contact pad in electrical communication with the selected one of the plurality of electrical conduits and located on the second surface.

A20. The interposer of any of paragraphs A18-A19, wherein a location of the at least a portion of the plurality of contact pads is based, at least in part, upon a location of a complementary structure with which the portion of the plurality of contact pads is configured to be in electrical communication.

A21. The interposer of any of paragraphs A18-A20, wherein a central axis of the at least a portion of the plurality of contact pads is not aligned with a central axis of the plurality of electrical conduits that are in electrical communication with the portion of the plurality of contact pads.

A22. The interposer of any of paragraphs A18-A21, wherein the at least a portion of the plurality of contact pads further includes at least one of an abrasion-resistant surface and a corrosion-resistant surface, optionally wherein the portion of the plurality of contact pads includes a surface layer configured to decrease at least one of wear and corrosion of the portion of the plurality of contact pads, and further optionally wherein the surface layer includes at least one of hardened gold, ruthenium, and rhodium.

A23. The interposer of any of paragraphs A18-A22, wherein a minimum length of each of the plurality of contact pads is less than 150 um, optionally including a minimum length of less than 140 um, less than 130 um, less than 120 um, less than 110 um, less than 100 um, less than 90 um, less than 80 um, less than 70 um, less than 60 um, less than 50 um, less than 40 um, less than 30 um, less than 20 um, less than 15 um, or less than 10 um.

A24. The interposer of any of paragraphs A18-A23, wherein a root mean square surface roughness of each of the plurality of contact pads is less than 10 um, optionally including a root mean square surface roughness of less than 9 um, less than 8 um, less than 7 um, less than 6 um, less than 5 um, less than 4 um, less than 3 um, less than 2 um, less than 1 um, less than 0.5 um, or less than 0.25 um.

A25. The interposer of any of paragraphs A1-A14, wherein the interposer is configured to provide a plurality of electrical connections between a first device, which is in electrical communication with the first surface, and a second device, which is in electrical communication with the second surface.

A26. The interposer of paragraph A25, wherein the interposer is formed on the first device, and optionally wherein the interposer is not configured to be removed from the first device without at least one of destruction to and damage of at least one of the interposer, the first device, and/or an optional attachment structure that secures the interposer to the first device.

A27. The interposer of any of paragraphs A25-A26, wherein the plurality of electrical conduits is formed on the first device, and further wherein the solid dielectric material is subsequently applied to the first device to form the interposer.

A28. The interposer of any of paragraphs A25-A27, wherein the interposer is formed in the first device.

A29. The interposer of paragraph A28, wherein the plurality of electrical conduits is formed by at least one of insertion into the first device, insertion into a void present within the first device, deposition into a void within the first device, plating into a void present within the first device, and incorporation of a conductivity-increasing material into the first device.

A30. The interposer of any of paragraphs A25-A29, wherein the solid dielectric material is applied to the first device, and further wherein the plurality of electrical conduits is subsequently formed within the solid dielectric material.

A31. The interposer of paragraph A30, wherein the plurality of electrical conduits is formed by at least one of insertion into the solid dielectric material, insertion into a void present within the solid dielectric material, deposition into a void within the solid dielectric material, plating into a void formed within the solid dielectric material, and incorporation of a conductivity-increasing material into the solid dielectric material.

A32. The interposer of paragraph A25, wherein the interposer is formed on an intermediate surface and subsequently placed in electrical communication with the first device and the second device.

A33. The interposer of paragraph A32, wherein the interposer is operatively attached to at least one of, and optionally both, the first device and the second device.

A34. The interposer of paragraph A33, wherein the interposer is at least one of soldered to and adhered to at least one of, and optionally both, of the first device and the second device, and optionally wherein the interposer is adhered to at least one of the first device and the second device with a conductive adhesive.

A35. The interposer of any of paragraphs A32-A33, wherein the interposer is mechanically pressed into electrical contact with at least one of, and optionally both, the first device and the second device.

A36. The interposer of any of paragraphs A1-A35, wherein a pitch of the plurality of electrical conduits is less than 150 um, optionally including a pitch of less than 140 um, less than 130 um, less than 120 um, less than 110 um, less than 100 um, less than 90 um, less than 80 um, less than 70 um, less than 60 um, less than 50 um, less than 40 um, less than 30 um, less than 20 um, less than 15 um, or less than 10 um.

A37. The interposer of any of paragraphs A1-A36, wherein the plurality of electrical conduits includes at least 1,000 electrical conduits, optionally including at least 2,000, at least 2,500, at least 5,000, at least 10,000, at least 15,000, at least 20,000, at least 25,000, at least 50,000, at least 75,000, at least 100,000, at least 250,000, at least 500,000, at least 750,000, or at least 1,000,000 electrical conduits.

A38. The interposer of any of paragraphs A1-A37, wherein an aspect ratio of at least a portion of the plurality of electrical conduits is at least 10:1, optionally including an aspect ratio of at least 12:1, at least 14:1, at least 16:1, at least 18:1, at least 20:1, at least 22:1, at least 24:1, at least 26:1, at least 28:1, or at least 30:1.

A39. The interposer of any of paragraphs A1-A38, wherein a/the length of the plurality of electrical conduits is greater than 25 um, optionally including lengths of 50-500 um, 100-400 um, 200-350 um, 150-300 um, greater than 50 um, greater than 75 um, greater than 100 um, greater than 150 um, greater than 200 um, greater than 250 um, or greater than 300 um.

A40. The interposer of any of paragraphs A1-A39, wherein at least a portion of the plurality of electric currents includes a magnitude of at least 0.5 amps, optionally including a magnitude of at least 0.75 amps, at least 1 amp, at least 1.25 amps, at least 1.5 amps, at least 1.75 amps, at least 2 amps, at least 2.25 amps, at least 2.5 amps, at least 3 amps, at least 3.5 amps, at least 4 amps, or at least 5 amps.

A41. The interposer of any of paragraphs A1-A40, wherein at least a portion of the plurality of electric currents is applied with a duty cycle of at least 10%, optionally including a duty cycle of at least 15%, at least 20%, at least 25%, at least 30%, at least 35%, or at least 40%.

A42. The interposer of any of paragraphs A1-A41, wherein a plane defined by the first surface is within a threshold amount of being parallel to a plane defined by the second surface, and optionally wherein the threshold amount is less than 15 um, less than 14 um, less than 12 um, less than 10 um, less than 8 um, less than 6 um, or less than 5 um.

A43. The interposer of any of paragraphs A1-A42, wherein a longitudinal axis of each of the plurality of electrical conduits is at least substantially perpendicular to at least one of the first surface and the second surface, optionally wherein the longitudinal axis is within a threshold angle of being perpendicular to at least one of the first surface and the second surface, and further optionally wherein the threshold angle includes an angle of less than 10 degrees, less than 8 degrees, less than 6 degrees, less than 4 degrees, or less than 2 degrees.

A44. The interposer of any of paragraphs A1-A43, wherein the solid dielectric material includes at least one of a polymer, a semiconductor, an epoxy, silicon oxide, a polyimide, a photopolymer, and spin-on-glass, optionally wherein the solid dielectric material is at least one of rigid and non-elastomeric.

A45. The interposer of any of paragraphs A1-A44, wherein the solid dielectric material defines an external shape of the interposer.

A46. The interposer of any of paragraphs A1-A45, wherein the first surface and the second surface are formed, at least in part, from the solid dielectric material, and optionally wherein the first surface and the second surface are formed at least substantially from the solid dielectric material.

A47. The interposer of any of paragraphs A1-A46, wherein the body includes an at least substantially rigid body, optionally wherein the body is not resilient, and further optionally wherein the body is not elastic.

A48. The interposer of any of paragraphs A1-A47, wherein the plurality of electrical conduits is at least substantially rigid, and optionally wherein the plurality of electrical conduits is not resilient, further optionally wherein the plurality of electrical conduits is not elastic, and further optionally wherein the plurality of electrical conduits does not include a plurality of springs.

A49. The interposer of any of paragraphs A1-A48, wherein the interposer includes a layered structure that includes a plurality of interposer layers.

A50. A layered interposer configured to provide a plurality of electrical connections between a first surface of the layered interposer and a second, substantially opposed, surface of the layered interposer, the layered interposer comprising:

a plurality of layers, wherein each of the plurality of layers includes the interposer of any of paragraphs A1-A48, and further wherein the plurality of electrical connections are formed by a plurality of composite electrical conduits that include at least one electrical conduit in each of the plurality of layers.

A51. The layered interposer of paragraph A50, wherein the layered interposer further includes at least one passive electronic component between two or more adjacent layers.

A52. The layered interposer of paragraph A51, wherein the at least one passive electronic component includes at least one of a resistor, a capacitor, an inductor, a transformer, and an electrical conduit.

A53. The layered interposer of any of paragraphs A51-A52, wherein the at least one passive electronic component is configured to electrically connect at least two of the plurality of composite electrical conduits.

A54. The layered interposer of any of paragraphs A51-A53, wherein the plurality of composite electrical conduits includes a plurality of ground conduits, and further wherein the at least one passive electronic component is configured to electrically connect at least a portion, optionally a substantial portion, optionally a majority, and further optionally all of the plurality of ground conduits.

A55. The layered interposer of any of paragraphs A51-A54, wherein the plurality of composite electrical conduits includes a plurality of power supply conduits, and further wherein the at least one passive electronic component is configured to electrically connect at least a portion, optionally a substantial portion, optionally a majority, and further optionally all of the plurality of power supply conduits.

B1. A riser configured to extend and conduct a plurality electrical currents between a space transformer assembly and a fine pitch interposer in a probe head assembly, the riser comprising:

the interposer of any of paragraphs A1-A55, wherein the first surface is in electrical communication with the space transformer assembly, and further wherein the second surface is in electrical communication with the fine pitch interposer, and optionally wherein the first surface is in electrical and physical communication with the space transformer assembly, and further optionally wherein the second surface is in physical and electrical communication with the fine pitch interposer.

C1. A probe head assembly configured to form a plurality of electrical contacts with a device under test, the probe head assembly comprising:

a space transformer assembly;

the riser of paragraph B1, wherein the first surface of the riser/interposer is in physical and electrical communication with the space transformer assembly; and

a device under test contacting assembly, wherein a first surface of the device under test contacting assembly is in electrical communication with the riser, and further wherein a second surface of the device under test contacting assembly includes a plurality of probe tips configured to electrically contact the device under test, and optionally wherein the plurality of probe tips are configured to electrically and physically contact the device under test.

C2. The probe head assembly of paragraph C1, wherein the probe head assembly further includes a fine pitch interposer between the riser and the device under test contacting assembly, wherein a first surface of the fine pitch interposer is in physical and electrical communication with the second surface of the riser/interposer, and further wherein a second surface of the fine pitch interposer is in physical and electrical communication with the first surface of the device under test contacting assembly.

C3. The probe head assembly of any of paragraphs C1-C2, wherein the device under test contacting assembly includes a membrane contacting layer that includes the plurality of probe tips.

C4. The probe head assembly of paragraph C3, wherein at least a portion of the plurality of probe tips includes a plurality of rocking beam interposers.

C5. A probe head assembly configured to form a plurality of electrical contacts with a device under test, the probe head assembly comprising:

a space transformer including a plurality of space transformer electrical pads;

a device under test contacting assembly including a plurality of probe tips configured to form the plurality of electrical contacts with the device under test; and

a riser, wherein the riser is located between the space transformer and the device under test contacting assembly, and further wherein the riser includes a plurality of riser electrical conduits configured to conduct a plurality of electric currents between the plurality of space transformer electrical pads and the plurality of probe tips.

C6. The probe head assembly of paragraph C5, wherein the riser includes the interposer of any of paragraphs A1-A55 or the riser of paragraph B1, and optionally wherein the plurality of electrical conduits define the plurality of riser electrical conduits.

C7. The probe head assembly of any of paragraphs C5-C6, wherein the riser includes a substantially planar body, wherein the body defines a first surface of the riser and a second surface of the riser that is at least substantially opposed to the first surface of the riser, wherein the body includes a solid dielectric material that contains the plurality of riser electrical conduits, and further wherein the first surface of the riser is in physical and electrical communication with the space transformer.

C8. The probe head assembly of any of paragraphs C5-C7, wherein the probe head assembly further includes a fine pitch interposer, wherein the fine pitch interposer is located between the riser and the device under test contacting assembly and includes a plurality of fine pitch interposer electrical conduits configured to conduct the plurality of electric currents between the plurality of riser electrical conduits and the plurality of probe tips.

C9. The probe head assembly of paragraph C8, wherein the fine pitch interposer is in physical and electrical contact with the riser.

C10. The probe head assembly of any of paragraphs C8-C9, wherein the fine pitch interposer is in physical and electrical contact with the device under test contacting assembly.

C11. The probe head assembly of any of paragraphs C5-C10, wherein the probe head assembly further includes a space transformer assembly that includes the space transformer, and optionally includes at least one of a wide pitch interposer and a wide pitch riser that extends and conducts the plurality of electric currents between the space transformer and the wide pitch interposer.

D1. A test system configured to electrically test a device under test, the test system comprising:

the probe head assembly of any of paragraphs C1-C11;

a signal generator configured to provide a test signal to the device under test; and

a signal analyzer configured to receive a resultant signal from the device under test.

D2. The test system of paragraph D1, wherein the test system further includes an enclosure configured to contain at least a portion of the probe head assembly and the device under test.

D3. The test system of any of paragraphs D1-D2, wherein the test system further includes a control system configured to control the operation of the test system.

E1. A method of forming an interposer that includes a plurality of electrical conduits configured to transmit a plurality of electric currents between a first surface of the interposer and a second, substantially opposed, surface of the interposer, the method comprising:

aligning a plurality of electrical conduits to a surface of a substrate; and

encapsulating the plurality of electrical conduits within a solid body formed from a solid dielectric material.

E2. The method of paragraph E1, wherein the plurality of electrical conduits includes a metallic wire, and further wherein the aligning includes attaching the metallic wire to the substrate.

E3. The method of any of paragraphs E1-E2, wherein the plurality of electrical conduits includes a plurality of ferromagnetic wires, and further wherein the aligning includes applying a magnetic field to the plurality of ferromagnetic wires.

E4. The method of paragraph E3, wherein the plurality of ferromagnetic wires is configured to form an electrical connection between a plurality of electrical pads that is in electrical communication with the first surface and a plurality of electrical pads that is in electrical communication with the second surface, wherein the plurality of electrical pads that is in electrical communication with the first surface includes a first pad spacing, wherein the plurality of electrical pads that is in electrical communication with the second surface includes a second pad spacing, wherein an average diameter of the plurality of ferromagnetic wires is less than both the first pad spacing and the second pad spacing, and further wherein an average spacing among the plurality of ferromagnetic wires is less than both the first pad spacing and the second pad spacing.

E5. The method of any of paragraphs E2-E4, wherein the metallic wire is formed prior to performing the method.

E6. The method of paragraph E1, wherein the plurality of electrical conduits includes a plurality of metallic bump pads that are in electrical communication with one another and operatively attached to one another to form a stack of metallic bump pads.

E7. The method of paragraph E6, wherein the aligning includes attaching a first metallic bump pad to the substrate, and further wherein the aligning includes subsequently attaching at least a second metallic bump pad to the first metallic bump pad to form a stack of metallic bump pads.

E8. The method of any of paragraphs E6-E7, wherein the aligning includes attaching a subsequent metallic bump pad to a prior metallic bump pad, wherein the prior metallic bump pad includes a metallic bump pad that was previously attached to the stack of metallic bump pads, and further optionally wherein the aligning includes repeating the attaching a subsequent metallic bump pad to produce a desired length of the stack of metallic bump pads.

E9. The method of paragraph E1, wherein the aligning includes forming the plurality of electrical conduits on the surface of the substrate.

E10. The method of paragraph E9, wherein the forming includes depositing a conductive layer on the surface of the substrate and patterning the conductive layer to produce the plurality of electrical conduits.

E11. The method of paragraph E10, wherein the depositing includes at least one of physical vapor deposition, chemical vapor deposition, evaporation, sputtering, epitaxial growth, and plating.

E12. The method of any of paragraphs E10-E11, wherein the patterning includes lithographically defining a location for the plurality of electrical conduits.

E13. The method of any of paragraphs E10-E12, wherein the patterning includes etching the conductive layer to define the plurality of electrical conduits.

E14. The method of any of paragraphs E1-E13, wherein the aligning includes attaching the plurality of electrical conduits directly to the surface of the substrate.

E15. The method of any of paragraphs E1-E13, wherein the aligning includes attaching the plurality of electrical conduits to an intermediate layer that is formed on the surface of the substrate.

E16. The method of any of paragraphs E1-E15, wherein the aligning includes adhering the plurality of electrical conduits to the surface of the substrate.

E17. The method of any of paragraphs E1-E16, wherein the aligning includes at least one of soldering, welding, brazing, and spot welding the plurality of electrical conduits to the substrate.

E18. The method of any of paragraphs E1-E17, wherein the aligning includes alloying at least a portion of each of the plurality of electrical conduits with at least a portion of the surface of the substrate.

E19. The method of any of paragraphs E1-E18, wherein the aligning includes establishing electrical communication between the plurality of electrical conduits and the surface of the substrate.

E20. The method of any of paragraphs E1-E19, wherein the encapsulating includes flowing a liquid dielectric material on the surface of the substrate and around the plurality of electrical conduits.

E21. The method of paragraph E20, wherein the encapsulating includes placing an encapsulation dam on the surface of the substrate to constrain a flow of the liquid dielectric material prior to flowing the liquid dielectric material on the surface of the substrate.

E22. The method of any of paragraphs E1-E21, wherein the encapsulating includes curing a/the liquid dielectric material to form the solid dielectric material.

E23. The method of any of paragraphs E1-E22, wherein the substrate includes an intermediate substrate, and the method further includes removing the interposer from the intermediate substrate.

E24. The method of paragraph E23, wherein the removing includes at least one of dissolving the intermediate substrate, dissolving a sacrificial layer that forms a surface of the intermediate substrate, and separating the interposer from the intermediate substrate.

F1. A method of forming an interposer that includes a plurality of electrical conduits configured to transmit a plurality of electric currents between a first surface of the interposer and a second, substantially opposed, surface of the interposer, the method comprising:

forming a plurality of voids in a solid body; and

placing an electrically conductive material in the plurality of voids to form the plurality of electrical conduits.

F2. The method of paragraph F1, wherein the plurality of voids include at least one of a hole and a trench.

F3. The method of any of paragraphs F1-F2, wherein the forming includes lithographically forming the plurality of voids.

F4. The method of paragraph F3, wherein the lithographically forming further includes developing the plurality of voids.

F5. The method of any of paragraphs F1-F4, wherein the forming includes drilling the plurality of voids, and optionally wherein the forming includes drilling the plurality of voids with a drill bit.

F6. The method of any of paragraphs F1-F5, wherein the forming includes ablating a portion of the solid body to form the plurality of voids.

F7. The method of paragraph F6, wherein the ablating includes at least one of laser ablating and electron beam ablating.

F8. The method of any of paragraphs F1-F7, wherein the forming includes etching away a portion of the body to form the plurality of voids, and optionally wherein the etching includes at least one of chemical etching, wet etching, dry etching, and plasma etching.

F9. The method of any of paragraphs F1-F8, wherein the placing includes supplying at least a first portion of the electrically conductive material from a side of the interposer that is defined by the first surface, and optionally where the placing includes placing at least a second portion of the electrically conductive material from a side of the interposer that is defined by the second surface.

F10. The method of paragraph F9, wherein the plurality of voids includes a selected void, wherein the placing includes placing the at least a first portion of the electrically conductive material into the selected void from the side of the interposer that is defined by the first surface, and further wherein the placing includes placing the at least a second portion of the electrically conductive material into the selected void from a/the side of the interposer that is defined by the second surface.

F11. The method of any of paragraphs F9-F10, wherein prior to the placing, the method includes depositing an intermediate layer on the solid body, optionally wherein the intermediate layer includes at least one of a seed layer, a barrier layer, and a conductive layer, and further optionally wherein the depositing includes depositing the intermediate layer on a surface of the solid body that defines at least a portion of the plurality of voids.

F12. The method of any of paragraphs F1-F11, wherein the solid body is operatively attached to a substrate.

F13. The method of paragraph F12, wherein at least a portion of the plurality of voids is in fluid communication with a plurality of conductive pads on a surface of the substrate.

F14. The method of paragraph F13, wherein subsequent to the forming, the method further includes cleaning the plurality of conductive pads, wherein the cleaning includes removing a surface contaminant from the plurality of conductive pads.

F15. The method of any of paragraphs F12-F14, wherein, subsequent to the placing, the method further includes removing the interposer from the substrate, optionally wherein the removing includes dissolving at least a sacrificial portion of the substrate, optionally wherein the sacrificial portion of the substrate includes a different chemical composition than a remaining portion of the substrate, and further optionally wherein the sacrificial portion of the substrate includes the entire substrate.

F16. The method of any of paragraphs F1-F15, wherein the placing includes inserting the electrically conductive material into the plurality of voids to form the plurality of electrical conduits.

F17. The method of paragraph F16, wherein the electrically conductive material includes at least one of a wire and a stack of metallic bump pads.

F18. The method of any of paragraphs F1-F17, wherein the placing includes depositing the electrically conductive material within the plurality of voids.

F19. The method of paragraph F18, wherein the depositing includes at least one of physical vapor deposition, chemical vapor deposition, screening, epitaxially growing, sputtering, and plating.

F20. The method of any of paragraphs F18-F19, wherein, prior to the depositing, the method includes coating at least one, and optionally both, of the first surface and the second surface with a masking photoresist and patterning the masking photoresist.

F21. The method of paragraph F20, wherein the patterning the masking photoresist includes removing a portion of the masking photoresist that covers the at least a portion of the plurality of voids.

F22. The method of any of paragraphs F20-F21, wherein, subsequent to the depositing, the method further includes removing the masking photoresist.

F23. The method of any of paragraphs F1-F22, wherein the method further includes forming the solid body prior to forming the plurality of voids.

F24. The method of any of paragraphs F1-F23, wherein the solid body includes a solid dielectric material, and optionally wherein forming the solid body includes at least one of flowing the solid dielectric material onto a surface of a substrate, coating the solid dielectric material onto the surface of the substrate, depositing the solid dielectric material onto the surface of the substrate, casting the solid dielectric material, extruding the solid dielectric material, blowing the solid dielectric material, and curing the solid dielectric material to form the solid body.

F25. The method of any of paragraphs F12-F23, wherein the solid body includes a matrix material, and optionally wherein the matrix material includes at least one of a solid dielectric material, photoresist, copper, silicon oxide, and a material that possesses a high etch selectivity relative to the electrically conductive material.

F26. The method of paragraph F25, wherein forming the matrix material includes at least one of flowing the matrix material onto a surface of a substrate, coating the matrix material onto the surface of the substrate, depositing the matrix material onto the surface of the substrate, casting the matrix material, extruding the matrix material, blowing the matrix material, and curing the matrix material to form the solid body.

F27. The method of any of paragraphs F25-F26, wherein the method further includes repeating the method.

F28. The method of any of paragraphs F25-F27, wherein the method further includes removing the matrix material from around the plurality of electrical conduits to form a plurality of unsupported electrical conduits, and optionally wherein the removing includes at least one of etching the matrix material and dissolving the matrix material.

F29. The method of paragraph F28, wherein the method further includes encapsulating the plurality of unsupported electrical conduits in a dielectric material.

F30. The method of paragraph F29, wherein the encapsulating includes performing the method of any of paragraphs E1-E24, and further wherein the aligning includes forming the plurality of unsupported electrical conduits.

G1. A method of forming an interposer that includes a plurality of electrical conduits configured to transmit a plurality of electric currents between a first surface of the interposer and a second, substantially opposed, surface of the interposer, the method comprising:

placing a solid body formed from a dielectric material on a surface of a substrate; and

incorporating a conductivity-enhancing material into a plurality of selected portions of the dielectric material to form the plurality of electrical conduits.

G2. The method of paragraph G1, wherein the dielectric material includes a semiconductor material, and optionally wherein the dielectric material includes at least one of silicon, gallium arsenide, germanium, and a semiconducting polymer.

G3. The method of any of paragraphs G1-G2, wherein the conductivity-enhancing material includes a dopant, and optionally wherein the incorporating includes implanting the dopant into the dielectric material.

G4. The method of any of paragraphs G1-G3, wherein the placing includes at least one of physical vapor deposition, chemical vapor deposition, evaporation, sputtering, spin-coating, laminating, dipping, and flowing.

G5. The method of any of paragraphs G1-G4, wherein the substrate includes an intermediate substrate, and the method further includes removing the interposer from the intermediate substrate.

G6. The method of paragraph G5, wherein the removing includes at least one of dissolving the intermediate substrate, dissolving a sacrificial layer that forms a surface of the intermediate substrate, and separating the interposer from the intermediate substrate.

G7. The method of any of paragraphs G1-G7, wherein the dielectric material includes a solid dielectric material.

H1. The method of any of paragraphs E1-G7, wherein the method further includes annealing the interposer, and optionally wherein the annealing includes heating the interposer.

H2. The method of any of paragraphs E1-H1, wherein the method further includes polishing at least one, and optionally both, of the first surface and the second surface to produce a target interposer thickness, wherein, subsequent to the polishing, the plurality of electrical conduits extends from the first surface to the second surface.

H3. The method of paragraph H2, wherein the polishing includes at least one of decreasing a thickness of the solid body, decreasing a length of the plurality of electrical conduits, decreasing a surface roughness of the interposer, increasing a parallelism between a plane defined by the first surface and a plane defined by the second surface, and exposing an end of the plurality of electrical conduits that is proximal to at least one of the first surface and the second surface.

H4. The method of any of paragraphs E1-H3, wherein the solid body includes at least one of a polymer, a semiconductor, an epoxy, silicon oxide, a polyimide, a photopolymer, and spin-on-glass.

H5. The method of any of paragraphs E1-H4, wherein the plurality of electrical conduits includes at least one of a metal, copper, a copper alloy, gold, a gold alloy, one or more carbon nanotubes, graphene, and a doped semiconductor material.

H6. The method of any of paragraphs E1-H5, wherein the interposer includes a plurality of contact pads, wherein at least a portion of the plurality of contact pads is in electrical communication with at least one electrical conduit, and further wherein the method includes forming the plurality of contact pads.

H7. The method of paragraph H6, wherein the forming includes at least one, and optionally all, of forming an adhesion layer on at least one of the first surface and the second surface, lithographically defining a location of the plurality of contact pads, etching the adhesion layer to define a plurality of conductive bases, electroplating the plurality of conductive bases to form the plurality of contact pads, and capping the plurality of contact pads.

H8. The method of paragraph H7, wherein the capping includes coating the plurality of contact pads with a coating material, optionally wherein the coating material includes at least one of an abrasion-resistant coating material and a corrosion-resistant coating material, further optionally wherein the coating includes electroplating the plurality of contact pads with a noble metal, and further optionally wherein the noble metal includes at least one of hard gold, ruthenium, and rhodium.

H9. The method of any of paragraphs H6-H8, wherein the forming includes locating at least a portion of the plurality of contact pads based, at least in part, upon at least one of a location of a complementary structure with which the portion of the plurality of contact pads is configured to be in electrical communication and a location of a registration feature.

H10. The method of paragraph H9, wherein the locating does not include aligning a central axis of the portion of the plurality of contact pads with a central axis of the plurality of electrical conduits that are in electrical communication with the portion of the plurality of contact pads.

H11. The method of any of paragraphs H6-H10, wherein the plurality of contact pads includes a first contact pad on the first surface of the interposer and in electrical communication with a selected one of the plurality of electrical conduits and a second contact pad on the second surface of the interposer and in electrical communication with the selected one of the plurality of electrical conduits.

H12. The method of any of paragraphs H6-H11, wherein a minimum length of each of the plurality of contact pads is less than 150 um, optionally including minimum lengths of less than 140 um, less than 130 um, less than 120 um, less than 110 um, less than 100 um, less than 90 um, less than 80 um, less than 70 um, less than 60 um, less than 50 um, less than 40 um, less than 30 um, less than 20 um, less than 15 um, or less than 10 um.

H13. The method of any of paragraphs H6-H12, wherein a root mean square surface roughness of each of the plurality of contact pads is less than 10 um, optionally including a root mean square surface roughness of less than 9 um, less than 8 um, less than 7 um, less than 6 um, less than 5 um, less than 4 um, less than 3 um, less than 2 um, less than 1 um, less than 0.5 um, or less than 0.25 um.

H14. The method of any of paragraphs E1-H13, wherein the method further includes coating at least a portion of at least one of the first surface and the second surface with an abrasion-resistant material, optionally wherein the abrasion-resistant material includes an abrasion-resistant dielectric material, and further optionally wherein the portion of at least one of the first surface and the second surface includes a sub-portion of at least one of the first surface and the second surface that does not include a/the plurality of contact pads.

H15. The method of any of paragraphs E1-H14, wherein the method further includes repeating the method, and optionally wherein the repeating includes repeating the method to increase at least one of an interposer thickness, a length of the plurality of electrical conduits, and an aspect ratio of the plurality of electrical conduits.

H16. The method of paragraph H15 when dependent from any of paragraphs E1-E22, F12-F15, or G1-G4 wherein, prior to the repeating, the interposer includes an upper surface, and further wherein the repeating includes utilizing the upper surface as the surface of the substrate during the repeating.

H17. The method of paragraph H15 when dependent from any of paragraphs E23-E24, F1-F11, F16-F24, or G5-G7, wherein, prior to the repeating, the interposer includes an upper surface, and further wherein the repeating includes applying a layer of dielectric material (and optionally applying a layer of the solid dielectric material) to the upper surface, wherein the forming a/the plurality of voids includes forming the plurality of voids in the layer of (solid) dielectric material, and further wherein the placing an/the electrically conductive material includes placing the electrically conductive material in the plurality of voids that were formed in the layer of dielectric material.

H18. The method of any of paragraphs H16-H17, where, prior to the repeating, the method includes adding at least one passive electronic component to the upper surface of the interposer.

H19. The method of paragraph H18, wherein the at least one passive electronic component includes at least one of a resistor, a capacitor, an inductor, a transformer, and an electrical conduit.

H20. The method of any of paragraphs H18-H19, wherein the at least one passive electronic component is configured to electrically connect at least a portion of the plurality of electrical conduits.

H21. The method of any of paragraphs H18-H19, wherein the plurality of electrical conduits includes a plurality of ground conduits, and further wherein the at least one passive electronic component is configured to electrically connect at least a portion, optionally a substantial portion, optionally a majority, and further optionally all of the plurality of ground conduits.

H22. The method of any of paragraphs H18-H21, wherein the plurality of electrical conduits includes a plurality of power supply conduits, and further wherein the at least one passive electronic component is configured to electrically connect at least a portion, optionally a substantial portion, optionally a majority, and further optionally all of the plurality of power supply conduits.

H23. The method of any of paragraphs H15-H22, wherein the repeating includes repeating the method at least two times, optionally including repeating the method at least three, at least four, at least five, at least six, at least seven, at least eight, at least nine, or at least ten times.

H24. The method of any of paragraphs E1-H23, wherein a pitch of the plurality of electrical conduits is less than 150 um, optionally including a pitch of less than 140 um, less than 130 um, less than 120 um, less than 110 um, less than 100 um, less than 90 um, less than 80 um, less than 70 um, less than 60 um, less than 50 um, less than 40 um, less than 30 um, less than 20 um, less than 15 um, or less than 10 um.

H25. The method of any of paragraphs E1-H24, wherein the plurality of electrical conduits includes at least 1,000 electrical conduits, optionally including at least 2,000, at least 2,500, at least 5,000, at least 10,000, at least 15,000, at least 20,000, at least 25,000, at least 50,000, at least 75,000, at least 100,000, at least 250,000, at least 500,000, at least 750,000, or at least 1,000,000 electrical conduits.

H26. The method of any of paragraphs E1-H25, wherein an aspect ratio of at least a portion of the plurality of electrical conduits is at least 10:1, optionally including an aspect ratio of at least 12:1, at least 14:1, at least 16:1, at least 18:1, at least 20:1, at least 22:1, at least 24:1, at least 26:1, at least 28:1, or at least 30:1.

H27. The method of any of paragraphs E1-H26, wherein a length of the plurality of electrical conduits is greater than 25 um, optionally including a length of 50-500 um, 100-400 um, 200-350 um, 150-300 um, greater than 50 um, greater than 75 um, greater than 100 um, greater than 150 um, greater than 200 um, greater than 250 um, or greater than 300 um.

H28. The method of any of paragraphs E1-H27, wherein at least a portion of the plurality of electric currents includes a magnitude of at least 0.5 amps, optionally including a magnitude of at least 0.75 amps, at least 1 amp, at least 1.25 amps, at least 1.5 amps, at least 1.75 amps, at least 2 amps, at least 2.25 amps, at least 2.5 amps, at least 3 amps, at least 3.5 amps, at least 4 amps, or at least 5 amps.

H29. The method of any of paragraphs E1-H28, wherein at least a portion of the plurality of electric currents is applied with a duty cycle of at least 10%, optionally including a duty cycle of at least 15%, at least 20%, at least 25%, at least 30%, at least 35%, or at least 40%.

H30. The method of any of paragraphs E1-H29, wherein a/the plane defined by the first surface is within a threshold amount of being parallel to a/the plane defined by the second surface, and optionally wherein the threshold amount is less than 15 um, less than 14 um, less than 12 um, less than 10 um, less than 8 um, less than 6 um, or less than 5 um.

H31. The method of any of paragraphs E1-H30, wherein a longitudinal axis of the plurality of electrical conduits is at least substantially perpendicular to the surface of the substrate, optionally wherein the longitudinal axis is within a threshold angle of being perpendicular to the surface of the substrate, optionally wherein the threshold angle includes an angle of less than 10 degrees, less than 8 degrees, less than 6 degrees, less than 4 degrees, or less than 2 degrees, optionally wherein the plurality of electrical conduits includes a majority of the plurality of electrical conduits, and further optionally wherein the plurality of electrical conduits includes all of the plurality of electrical conduits.

H32. The method of any of paragraphs E23-E24, F1-F11, F16-F24, or G5-G7, wherein the method further includes assembling the interposer onto a substrate.

H33. The method of paragraph H32, wherein the assembling includes establishing electrical communication between the plurality of electrical conduits and a plurality of electrical pads on the substrate.

H34. The method of paragraph H33, wherein the establishing electrical communication includes at least one of adhering at least a portion of the interposer to at least a portion of the plurality of electrical pads with an electrically conductive adhesive and soldering at least a portion of the interposer to at least a portion of the plurality of electrical pads.

H35. The method of paragraph H34, wherein the portion of the interposer includes at least one of an end of the plurality of electrical conduits and at least a portion of a plurality of contact pads that are in electrical communication with the plurality of electrical conduits.

H36. The method of any of paragraphs H33-H35, wherein the establishing electrical communication includes depositing a heat-curing dielectric onto the substrate, removing a portion of the heat-curing dielectric to expose the plurality of electrical pads, replacing the removed portion of the heat-curing dielectric with a heat-curing electrically conductive adhesive, pressing the interposer into contact with the heat-curing dielectric and the heat-curing electrically conductive adhesive to form an interposer assembly, and heating the interposer assembly to cure the heat-curing dielectric and the heat-curing electrically conductive adhesive.

H37. The method of any of paragraphs H32-H36, wherein the method further includes forming a plurality of contact structures on at least one of the first surface and the second surface, wherein the plurality of contact structures are in electrical communication with the plurality of electrical conduits, wherein the method includes encapsulating the plurality of contact structures in a heat-setting resin, wherein the method includes pressing the plurality of contact structures into contact with a/the plurality of electrical pads to form an/the interposer assembly that includes an electrical connection between the plurality of contact structures and the plurality of electrical pads, and further wherein the method includes heating the interposer assembly to cure the heat-setting resin.

H38. The method of paragraph H37, wherein at least a portion of the plurality of contact structures includes a rocking beam interposer.

H39. The method of any of paragraphs H32-H38, wherein the method further includes backfilling a space between the interposer and the substrate with a dielectric material.

H40. The method of any of paragraphs E1-H39, wherein the substrate includes at least one of a space transformer, a customer package, a wide-pitch interposer, and a narrow-pitch interposer.

H41. The method of any of paragraphs E1-H40, wherein a coefficient of thermal expansion of the interposer is at least substantially similar to a coefficient of thermal expansion of the substrate, and optionally wherein the coefficient of thermal expansion of the interposer differs from the coefficient of thermal expansion of the substrate by less than 20%, less than 15%, less than 10%, less than 7.5%, less than 5%, less than 2.5%, less than 1%, or less than 0.5%.

I1. A method of testing a device under test, the method comprising:

forming an interposer using the method of any of paragraphs E1-H41;

placing the interposer within a probe head assembly configured to form a plurality of electrical connections with the device under test;

contacting the device under test with the probe head assembly;

providing a test signal to the device under test from the probe head assembly; and

receiving a resultant signal from the device under test by the probe head assembly.

J1. The use of the interposers of any of paragraphs A1-A55, the riser of paragraph B1, the probe head assemblies of any of paragraphs C1-C11, or the test systems of any of paragraphs D1-D3 with any of the methods of any of paragraphs E1-I1.

J2. The use of the methods of any of paragraphs E1-I1 with any of the interposers of any of paragraphs A1-A55, the riser of paragraph B1, the probe head assemblies of any of paragraphs C1-C11, or the test systems of any of paragraphs D1-D3.

J3. The use of any of the interposers of any of paragraphs A1-A55, the riser of paragraph B1, the probe head assemblies of any of paragraphs C1-C11, the test systems of any of paragraphs D1-D3 or the methods of any of paragraphs E1-41 to provide a/the plurality of electrical connections between a/the space transformer assembly and a/the device under test contacting assembly within a/the probe head assembly.

J4. The use of a riser that includes a plurality of high aspect ratio electrical conduits as a spacer in a probe head assembly, and optionally as a spacer between a space transformer and a device under test contacting assembly.

### INDUSTRIAL APPLICABILITY

The systems and methods disclosed herein are applicable to the electronics industry.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, when the disclosure, the preceding numbered paragraphs, or subsequently filed claims recite “a” or “a first” element or the equivalent thereof, such claims should be understood to include incorporation of one or more such elements, neither requiring nor excluding two or more such elements.

Applicants reserve the right to submit claims directed to certain combinations and subcombinations that are directed to one of the disclosed inventions and are believed to be novel and non-obvious. Inventions embodied in other combinations and subcombinations of features, functions, elements and/or properties may be claimed through amendment of those claims or presentation of new claims in that or a related application. Such amended or new claims, whether they are directed to a different invention or directed to the same invention, whether different, broader, narrower or equal in scope to the original claims, are also regarded as included within the subject matter of the inventions of the present disclosure.

1. A probe head assembly configured to form a plurality of electrical contacts with a device under test, the probe head assembly comprising:
a space transformer including a plurality of space transformer electrical pads;
a device under test contacting assembly including a plurality of probe tips configured to form the plurality of electrical contacts with the device under test; and
a riser, wherein the riser is located between the space transformer and the device under test contacting assembly, and further wherein the riser includes a plurality of riser electrical conduits configured to conduct a plurality of electric currents between the plurality of space transformer electrical pads and the plurality of probe tips.

2. The probe head assembly of claim 1, wherein an aspect ratio of the plurality of riser electrical conduits is at least 10:1.

3. The probe head assembly of claim 1, wherein a length of the plurality of riser electrical conduits is at least 25 micrometers.

4. The probe head assembly of claim 1, wherein the riser includes a substantially planar body, wherein the body defines a first surface of the riser and a second surface of the riser that is at least substantially opposed to the first surface of the riser, wherein the body includes a solid dielectric material that contains the plurality of riser electrical conduits, and further wherein the first surface of the riser is in physical and electrical communication with the space transformer.

5. The probe head assembly of claim 1, wherein the probe head assembly further includes a fine pitch interposer, wherein the fine pitch interposer is located between the riser and the device under test contacting assembly and includes a plurality of fine pitch interposer electrical conduits configured to conduct the plurality of electric currents between the plurality of riser electrical conduits and the plurality of probe tips.

6. The probe head assembly of claim 5, wherein the fine pitch interposer is in physical and electrical contact with the riser.

7. The probe head assembly of claim 6, wherein the fine pitch interposer is in physical and electrical contact with the device under test contacting assembly.

8. The probe head assembly of claim 1, wherein the probe head assembly further includes a space transformer assembly that includes the space transformer, a wide pitch interposer, and a wide pitch riser that extends and conducts the plurality of electric currents between the space transformer and the wide pitch interposer.

9. The probe head assembly of claim 1, wherein the device under test contacting assembly includes a membrane contacting layer that includes the plurality of probe tips, wherein the membrane contacting layer is maintained in tension within the probe head assembly.

10. The probe head assembly of claim 9, wherein at least a portion of the plurality of probe tips includes a plurality of rocking beam interposers.

11. The probe head assembly of claim 1, wherein the riser is formed from a substantially rigid dielectric material that contains the plurality of riser electrical conduits, and further wherein the plurality of electrical conduits is at least substantially rigid.

12. A test system configured to electrically test a device under test, the test system comprising:
the probe head assembly of claim 1;
a signal generator configured to provide a test signal to the device under test; and
a signal analyzer configured to receive a resultant signal from the device under test.

13. A method of electrically testing a device under test, the method comprising:
electrically contacting the device under test with the probe head assembly of claim 1;
providing a test signal to the device under test with the probe head assembly; and
receiving a resultant signal from the device under test with the probe head assembly.

14. An interposer, comprising:
a substantially planar body, wherein the body includes a first surface and an opposed second surface, and further wherein the body is formed from a solid dielectric material; and
a plurality of electrical conduits contained within the body and configured to conduct a plurality of electric currents between the first surface and the second surface, wherein each of the plurality of electrical conduits includes a plurality of metallic bump pads that are stacked on top of one another to form a stack of metallic bump pads.

15. The interposer of claim 14, wherein an aspect ratio of each of the plurality of electrical conduits is at least 10:1.

16. The interposer of claim 14, wherein a length of each of the plurality of electrical conduits is at least 25 micrometers.

17. The interposer of claim 14, wherein the body includes an at least substantially rigid body, and further wherein the plurality of electrical conduits is at least substantially rigid.

18. A layered interposer configured to provide a plurality of electrical connections between a first surface of the layered interposer and a second, substantially opposed, surface of the layered interposer, the layered interposer comprising:
a plurality of layers, wherein each of the plurality of layers includes the interposer of claim 14, and further wherein the plurality of electrical connections is formed by a plurality of composite electrical conduits that include at least one electrical conduit of the plurality of electrical conduits in each of the plurality of layers.

19. The layered interposer of claim 18, further comprising at least one passive electronic component that extends between at least two composite electrical conduits of the plurality of composite electrical conduits.

20. The layered interposer of claim 18, wherein an aspect ratio of each of the plurality of composite electrical conduits is at least 10:1, and further wherein a length of each of the plurality of composite electrical conduits is at least 25 micrometers.

21. A method of forming the interposer of claim 14, the method comprising:
aligning the plurality of electrical conduits to a surface of a substrate, wherein the aligning includes attaching a first metallic bump pad to the substrate and subsequently attaching at least a second metallic bump pad to the first metallic bump pad to form each stack of metallic bump pads;
flowing a liquid dielectric material on the surface of the substrate and around the plurality of electrical conduits to encapsulate the plurality of electrical conduits; and
curing the liquid dielectric material to form a solid dielectric material that defines the substantially planar body.

22. A method of forming an interposer that includes a plurality of electrical conduits configured to transmit a plurality of electric currents between a first surface of the interposer and a second, substantially opposed, surface of the interposer, the method comprising:
forming a plurality of voids in a solid body, wherein each of the plurality of voids extends between the first surface and the second surface; and
placing an electrically conductive material in the plurality of voids to form the plurality of electrical conduits, wherein the placing includes supplying at least a first portion of the electrically conductive material from a side of the interposer that is defined by the first surface and supplying at least a second portion of the electrically conductive material from a side of the interposer that is defined by the second surface.

23. The method of claim 22, wherein the placing is subsequent to the forming.

24. The method of claim 22, wherein the placing includes plating the electrically conductive material into the plurality of voids to form the plurality of electrical conduits.
